(19) United States
(12) Patent Application Publication
(10) Pub. No.: US 2007/0206399 A1
(43) Pub. Date: Sep. 6, 2007

(54) NONVOLATILE SEMICONDUCTOR MEMORY DEVICE

(75) Inventors: Eiichi Makino, Yokohama-shi (JP); Koji Hosono, Fujisawa-shi (JP); Kazushige Kanda, Kawasaki-shi (JP); Shigeo Ohshima, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/682,478

(22) Filed: Mar. 6, 2007

(30) Foreign Application Priority Data
Mar. 6, 2006 (JP) 2006-060332

(51) Int. Cl. G11C 5/02; G11C 5/06

(52) U.S. Cl. 365/63; 365/51

(57) ABSTRACT

A nonvolatile semiconductor memory device having a first memory cell array including a plurality of electrical reprogramming and erasable nonvolatile semiconductor memory cells formed in a first area of a semiconductor substrate, a second memory cell array including a plurality of electrical reprogramming and erasable nonvolatile semiconductor memory cells formed in a second area different from said first area of said semiconductor substrate, said first and second memory cell arrays being arranged in a first direction, and a first pad section for inputting data to and outputting data from said first memory cell array and said second memory cell array, said first pad section having a plurality of pads arranged between said first memory cell array and said second memory cell array along a second direction perpendicular to said first direction.

### CROSS-REFERENCE TO RELATED APPLICATIONS

This application is based on and claims the benefit of priority from the prior Japanese Patent Application No. 2006-060332, filed on Mar. 6, 2006, the entire contents of which are incorporated herein by reference.

### TECHNICAL FIELD

The present invention relates to a nonvolatile semiconductor memory device that can electrically rewrite and erase data.

### BACKGROUND OF THE INVENTION

Conventionally, EEPROM in which data can be electrically rewritten has been known as one of semiconductor memory devices. A NAND-type EEPROM (NAND-type flash memory) in particular in which a plurality of memory cells based on a unit for storing one bit are connected in series has attracted attention as a device that can be highly integrated. A NAND-type flash memory is used, for example, for a memory card for recording image data of a digital still camera. In recent years, a demand for a NAND-type flash memory from the market for a higher capacity and a higher speed has been increasing.

In a floor plan for one package of a NAND-type flash memory currently used for mass production, an arrangement region or arrangement regions is/are provided at one side or both sides of pads. Two planes based on a unit of one memory cell array are arranged left and right sides of the chip and the respective planes have, at the lower side thereof, page buffer blocks including a plurality of sense amplifiers and page buffers corresponding to the respective planes. A peripheral circuitry includes control circuits such as logic controller, sequence controller, high-voltage generation circuit, I/O buffer. NAND-type flash memory devices are described in Japanese Patent Publications Nos. 2002-093993, 2001-094040 and H08-139287

In order to cope with a layout of a plurality of planes (cell arrays) and an increased division number of planes in the future to satisfy the demand for a higher speed and a higher integration for providing a higher capacity, such a pad layout is required that suppresses a CR delay time due to the capacity between wirings caused by wiring resistance and an interlayer insulating film. In order to provide a higher capacity, memory chips in provided in a multilayer lamination structure is required. However, this requires a pad layout that suppresses a package/chip cost and that can reduce the size of a chip packaging area.

### SUMMARY OF THE INVENTION

According to an embodiment of the present invention, a nonvolatile semiconductor memory device including:
a first memory cell array including a plurality of electrical reprogramming and erasable nonvolatile semiconductor memory cells formed in a first area of a semiconductor substrate;
a second memory cell array including a plurality of electrical reprogramming and erasable nonvolatile semiconductor memory cells formed in a second area different from said first area of said semiconductor substrate, said first and second memory cell arrays being arranged in a first direction; and
   a first pad section for inputting data to and outputting data from said first memory cell array and said second memory cell array, said first pad section having a plurality of pads arranged between said first memory cell array and said second memory cell array along a second direction perpendicular to said first direction.

According to an embodiment of the present invention, a semiconductor device including:
a first nonvolatile semiconductor memory comprising:
   a first memory cell array including a plurality of electrical reprogramming and erasable nonvolatile semiconductor memory cells formed in a first area of a first semiconductor substrate;
   a second memory cell array including a plurality of electrical reprogramming and erasable nonvolatile semiconductor memory cells formed in a second area different from said first area of said first semiconductor substrate, said first and second memory cell arrays being arranged in a first direction; and
   a first pad section for inputting data to and outputting data from said first memory cell array and said second memory cell array, said first pad section having a plurality of pads arranged between said first memory cell array and said second memory cell array along a second direction perpendicular to said first direction; and
a second nonvolatile semiconductor memory comprising:
   a third memory cell array including a plurality of electrical reprogramming and erasable nonvolatile semiconductor memory cells formed in a third area of a second semiconductor substrate;
   a fourth memory cell array including a plurality of electrical reprogramming and erasable nonvolatile semiconductor memory cells formed in a fourth area different from said third area of said second semiconductor substrate, said third and fourth memory cell arrays being arranged in a first direction; and
   a second pad section for inputting data to and outputting data from said third memory cell array and said fourth memory cell array, said second pad section having a plurality of pads arranged between said third memory cell array and said fourth memory cell array along said second direction,
   wherein said first substrate and second substrate are stacked, and said plurality of pads in said first pad section and said plurality of pads in said second pad section are connected via a through hole wiring formed in respective substrates of said first and second nonvolatile semiconductor memory devices.

### BRIEF DESCRIPTION OF THE DRAWINGS

FIG. 1 is a top view illustrating a data wiring in a nonvolatile semiconductor memory device according to one embodiment of the present invention.

FIG. 2 is an in-block structure diagram of a nonvolatile semiconductor memory device according to one embodiment of the present invention.

FIG. 3 is an in-block structure diagram illustrating a cross section of a nonvolatile semiconductor memory device according to one embodiment of the present invention.

FIG. 4 is a schematic structure diagram illustrating a nonvolatile semiconductor memory device according to one embodiment of the present invention.

FIG. 5 is a top view illustrating a data wiring when a nonvolatile semiconductor memory device according to one embodiment of the present invention uses a configuration of sense amplifiers at both sides of a plane.

FIG. 6 is a top view illustrating a power wiring of a nonvolatile semiconductor memory device according to one embodiment of the present invention.

FIG. 7 is a diagram of three sides of layered chips of a nonvolatile semiconductor memory device according to one embodiment of the present invention.

FIG. 8 is a top view illustrating data wiring of a nonvolatile semiconductor memory device according to first embodiment of the present invention.

FIG. 9 is a top view illustrating a data wiring in a nonvolatile semiconductor memory device according to first embodiment of the present invention.

FIG. 10 is a top view illustrating a data wiring in a nonvolatile semiconductor memory device according to second embodiment of the present invention (in the case where single end S/As are used).

FIG. 11 is a top view illustrating a data wiring in a nonvolatile semiconductor memory device according to second embodiment of the present invention (in the case where shared S/As are used).

FIG. 12 is a top view illustrating a power source wiring of a nonvolatile semiconductor memory device according to second embodiment of the present invention (in the case where single end S/As are used).

FIG. 13 is a top view illustrating a data wiring in a nonvolatile semiconductor memory device according to second embodiment of the present invention (in the case where single end S/As are used).

FIG. 14 is a top view illustrating a data wiring in a nonvolatile semiconductor memory device according to third embodiment of the present invention (in the case where single end S/As are used).

FIG. 15 is a top view illustrating a data wiring in a nonvolatile semiconductor memory device according to third embodiment of the present invention (in the case where shared S/As are used).

FIG. 16 is a top view illustrating a power wiring in a nonvolatile semiconductor memory device according to third embodiment of the present invention (in the case where single end S/As are used).

FIG. 17 is a top view illustrating a power wiring in a nonvolatile semiconductor memory device according to third embodiment of the present invention (in the case where shared S/As are used).

FIG. 18 is a top view illustrating a data wiring in a nonvolatile semiconductor memory device according to fourth embodiment of the present invention (in the case where single end S/As are used).

FIG. 19 is a top view illustrating a data wiring in a nonvolatile semiconductor memory device according to fourth embodiment of the present invention (in the case where shared S/As are used).

FIG. 20 is a top view illustrating a power source wiring in a nonvolatile semiconductor memory device according to Illustrative fourth embodiment of the present invention (in the case where a single end S/A is used).

FIG. 21 is a top view illustrating a power wiring in a nonvolatile semiconductor memory device according to fourth embodiment of the present invention (in the case where shared S/As are used).

FIG. 22 is a top view illustrating a data wiring in a nonvolatile semiconductor memory device according to fourth embodiment of the present invention (in the case where single end S/As are used).

FIG. 23 is a top view illustrating a data wiring in a nonvolatile semiconductor memory device according to fourth embodiment of the present invention (in the case where shared S/As are used).

FIG. 24 is a top view illustrating a power wiring in a nonvolatile semiconductor memory device according to fourth embodiment of the present invention (in the case where single end S/As are used).

FIG. 25 is a top view illustrating a data wiring in a nonvolatile semiconductor memory device according to fourth embodiment of the present invention (in the case where shared S/As are used).

FIG. 26 is a top view illustrating a data wiring in a nonvolatile semiconductor memory device according to fifth embodiment of the present invention (in the case where single end S/As are used).

FIG. 27 is a top view illustrating a data wiring in a nonvolatile semiconductor memory device according to fifth embodiment of the present invention (in the case where shared S/As are used).

FIG. 28 is a top view illustrating a power wiring in a nonvolatile semiconductor memory device according to fifth embodiment of the present invention (in the case where single end S/As are used).

FIG. 29 is a top view illustrating a data wiring in a nonvolatile semiconductor memory device according to fifth embodiment of the present invention (in the case where shared S/As are used).

FIG. 30 is a top view illustrating a data wiring in a nonvolatile semiconductor memory device according to sixth embodiment of the present invention.

FIG. 31 illustrates a cross section of layered chips a nonvolatile semiconductor memory device according to seventh embodiment of the present invention.

FIG. 32 is a top view illustrating a data wiring by a core bypass wiring when a pad section is placed at a chip end (in the case where single end S/As are used).

FIG. 33 is a top view illustrating a data wiring by a PB penetration wiring when a pad section is placed at a chip end (in the case where single end S/As are used).

FIG. 34 is a top view illustrating a power wiring when a pad section is placed at a chip end (in the case where single end S/As are used).

FIG. 35 is a diagram of three sides of layered chips when a pad section is placed at a chip end.

FIG. 36 is a top view illustrating a data wiring by a core bypass wiring when a pad section is placed at a chip end (in the case where shared S/As are used).

FIG. 37 is a top view illustrating a data wiring by a core bypass wiring when a pad section is placed at a chip end (in the case where shared S/As are used).

FIG. 38 is a top view illustrating a data wiring by a core bypass wiring when a pad section is placed at a chip end (in the case where shared S/As are used).

FIG. 39 illustrates a cross section of layered chips by a wire bonding.

FIG. 40 is a top view illustrating a data wiring when a pad section is placed at a chip end and when a configuration of sense amplifiers at both sides of a plane is used.

### DETAILED DESCRIPTION OF THE INVENTION

Hereinafter, embodiments of a nonvolatile semiconductor memory device according to the present invention will be described in detail with reference to the drawings. It is noted that the embodiments show an example of a nonvolatile semiconductor memory device of the present invention and the nonvolatile semiconductor memory device of the present invention is not limited to these embodiments.

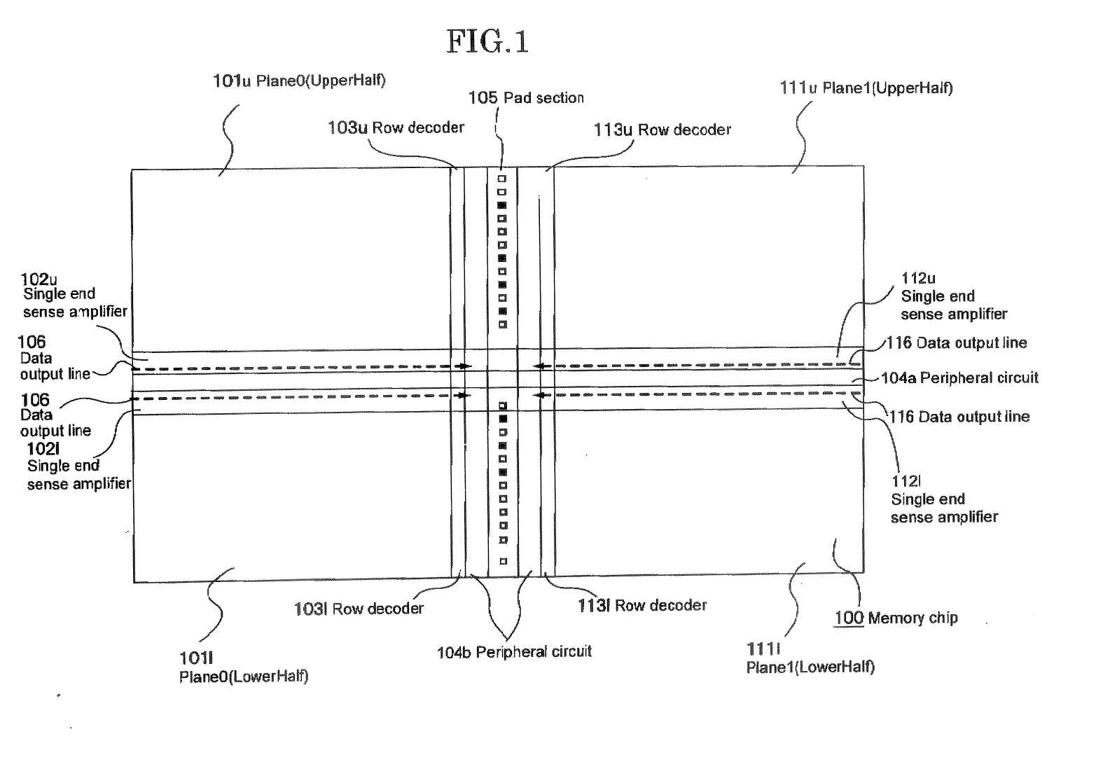

FIG. 1 is a schematic view of a chip layout of a NAND-type flash memory as an example of a nonvolatile semiconductor memory device according to one embodiment of the present invention. In this embodiment, each of two planes is dual-partitioned and a pad section is placed on a line connecting intermediate points of two long sides of a schematic substrate (hereinafter will be called as “on a chip long side center line”) and sense amplifiers are single end sense amplifiers (single end S/As).

In the NAND-type flash memory shown in FIG. 1, a memory chip 100 has thereon the two left and right planes (cell arrays) including a plurality of electrically rewritten memory cells arranged in a matrix-like manner. The respective planes are dual-partitioned to upper and lower parts to provide planes 101U, 101L, 111U, and 111L. A pad section 105 is provided on a chip long side center line that is sandwiched between peripheral circuitries 104b at left and right sides. The chip long side center line intersects with a line connecting intermediate points of two short sides of the schematic substrate (hereinafter referred to as “chip short side center line”) on which a peripheral circuitry 104a is similarly placed. The respective planes have thereon corresponding single end sense amplifiers (single end S/As) 102U, 102L, 112U, and 112L and row decoders 103U, 103L, 113U, and 113L. Toward the pad section 105 placed on the chip long side center line, data output lines 106 having output information of cell data rewriting/reading circuits (hereinafter page buffers) from planes 101U and 101L are wired. Similarly, data output lines 116 having output information of page buffers of planes 111U and 111L is wired to the pad section 105. In this case, the pad section 105 can be placed on the chip long side center line to provide substantially the same wiring length to the data output wirings 106 and 116.

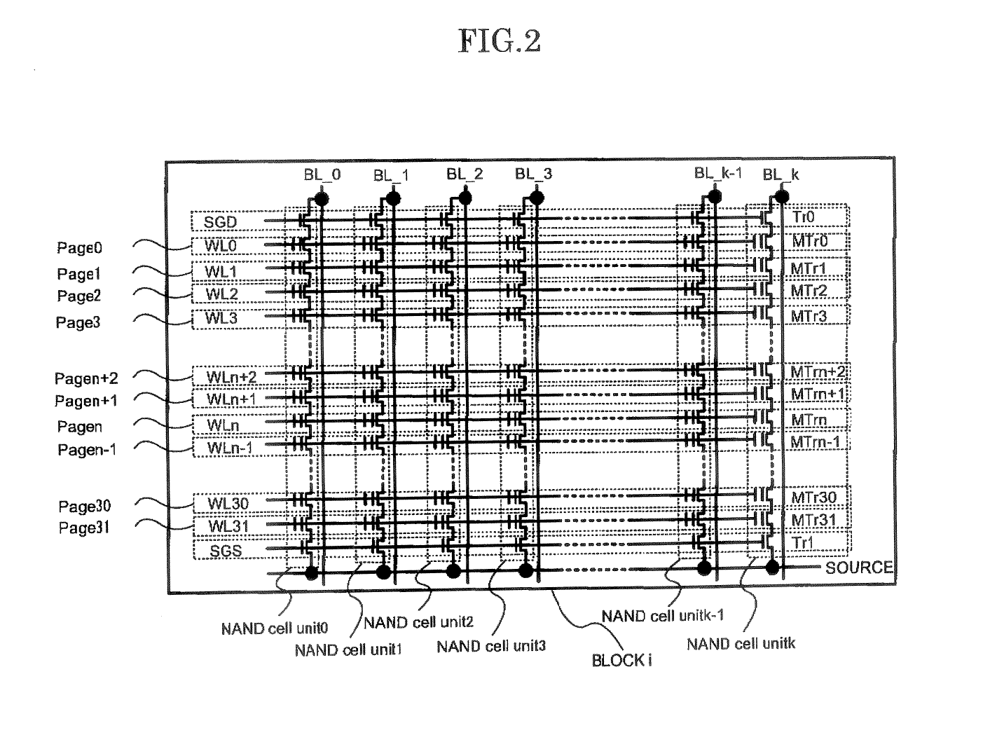

It is noted that cell arrays of the NAND-type flash memory shown in FIG. 1 as described above are divided to the total number “m” of blocks (BLOCK0, BLOCK1, BLOCK2, . . . BLOCKi, . . . BLOCKm). The term “block” means the minimum unit for data erasure. Each of the blocks BLOCK0 to BLOCKm is composed of “k” NAND cell units 0 to k as in a block BLOCKi typically shown in FIG. 2. In this embodiment, each NAND cell unit is composed of 32 memory cells MTr0 to MTr31 connected in series and one end thereof is connected, via a selection gate transistor Tr0 connected to a selection gate line SGD, to a bit line BL (BL_{—}0, BL_{—}1, BL_{—}2, BL_{—}3, . . . BL_k−1, BL_k) and the other end thereof is connected, via a selection gate transistor Tr1 connected to a selection gate line SGS, to a common source line SOURCE. The respective memory cells MTr have control gates connected to word lines WL (WL0 to WL31). The respective “k” memory cells MTr connected to one word line WL store one bit data and these “k” memory cells MTr constitute a unit of “page”.

In this embodiment, a memory cell array is composed of “m” blocks and one block includes “k” NAND cell units composed of 32 memory cells MTr. However, the invention is not limited to this. The number of blocks, the number of memory cells MTr, and the number of NAND cell units may be changed depending on a desired capacity. Additionally, in this embodiment, the respective memory cells MTr store 1 bit data. However, each memory cell MTr also may store data of a plurality of bits (multivalued bit data) depending on an amount of electronic injection. Furthermore, in this embodiment, an example of a NAND-type flash memory in which one NAND cell unit is connected to one bit line BL has been described. However, the NAND-type flash memory 1 of the present invention also may be applied to the so-called shared bit line-type NAND-type flash memory in which a plurality of NAND cell units share one bit line BL.

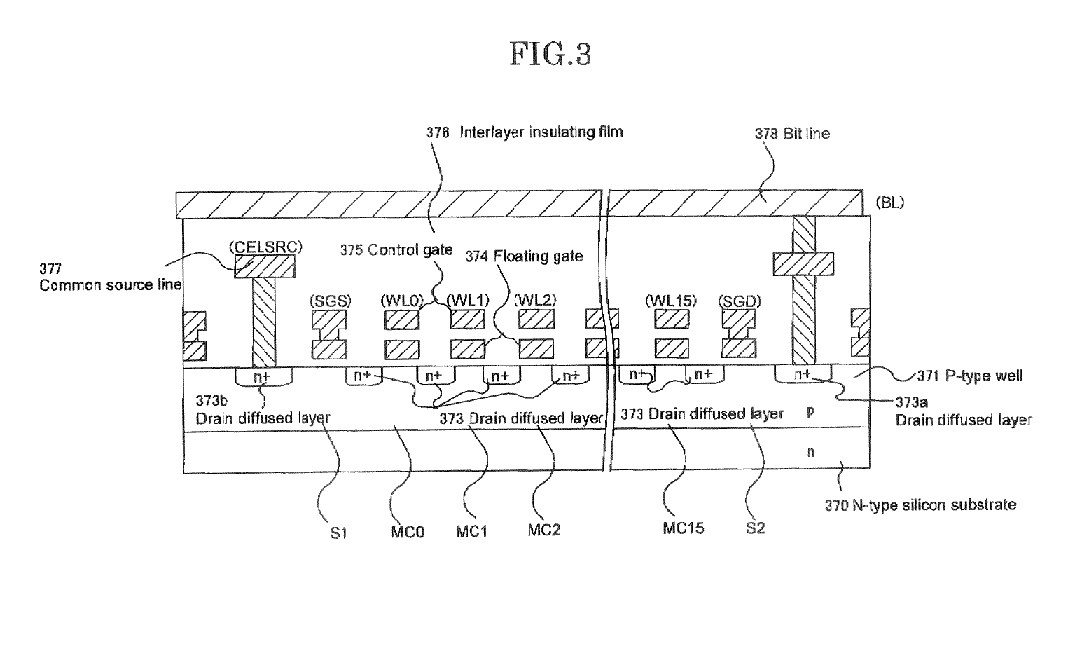

FIG. 3 shows a cross section along a bit line of one NAND cell unit of FIG. 2 as described above. Memory cells are formed in an n-type silicon substrate or a p-type well 371 formed in an n-type well 370. Neighboring memory cells share source/drain diffused layers 373. A memory cell has a layered structure of a floating gate 374 and a control gate 375. The control gate 375 is patterned to a word line WL common to a plurality of memory cells in a direction orthogonal to the surface of the drawing. A cell array is covered by an interlayer insulating film 376. A common source line (CELSRC) 377 in a block implanted in the interlayer insulating film 376 has a contact with a source diffused layer 373b of one selection gate transistor S1. A bit line (BL) 378 formed on the interlayer insulating film 376 has a contact with a drain diffused layer 373a of the other selection gate transistor S2. The contacts of these source line 377 and bit line 378 are shared by neighboring NAND cells.

As described above, a NAND-type flash memory is structured so that neighboring memory cells in a NAND cell unit share a diffused layer and neighboring NAND cell units share a wiring contact. Although the details will not be described, a direction orthogonal to the surface of FIG. 3 has element regions and element separation regions alternately arranged to draw a stripe pattern and memory cells are formed on the respective intersection points at which the respective element regions intersect with word lines WL having a stripe pattern orthogonal to the element regions. These structural features can realize a NAND-type flash memory that can have a higher density and a higher capacity and an effective unit cell area 5F² (F: minimum processing size).

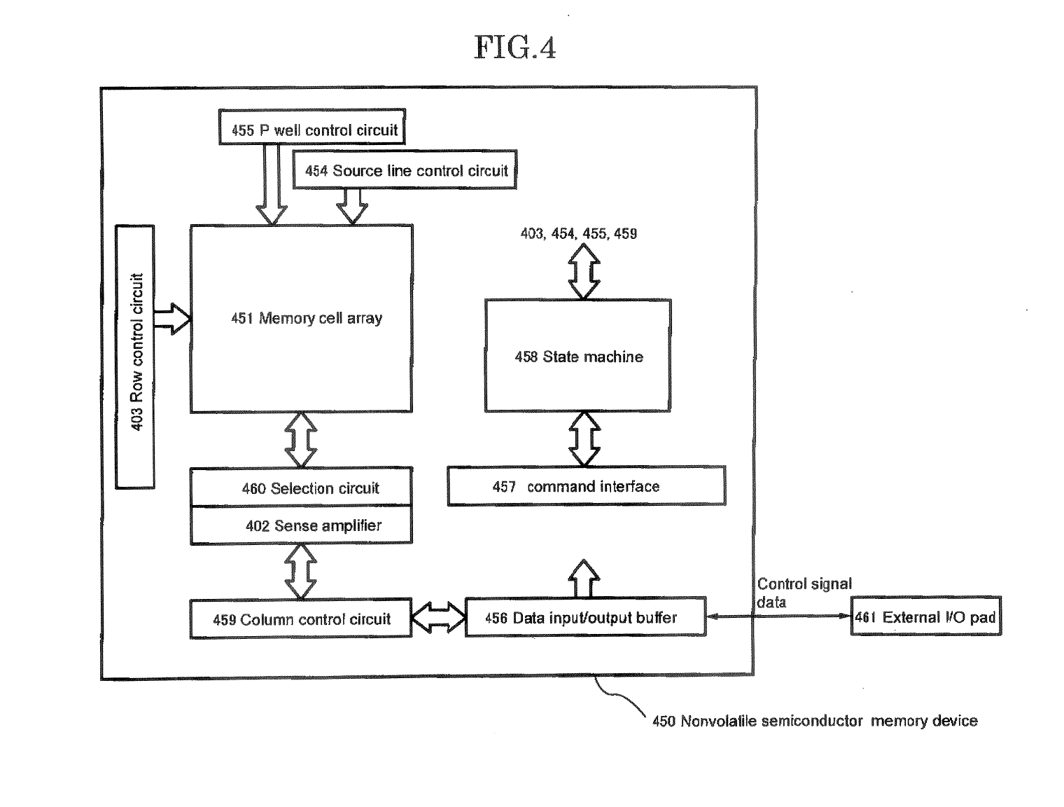

FIG. 4 is a schematic structure diagram illustrating a nonvolatile semiconductor memory device 450 according to one embodiment of the present invention. The nonvolatile semiconductor memory device 450 has a memory cell array 451, a column control circuit (column decoder) 459, a row control circuit (row decoder) 403, a source line control circuit 454, a P well control circuit 455, a data input/output buffer 456, a command interface 457, a state machine 458, sense amplifiers 402, and a selection circuit 460. The nonvolatile semiconductor memory device 450 of the present invention according to this embodiment transmits and receives data and a control signal (command) to and from an external I/O pad 461.

In the nonvolatile semiconductor memory device 450 according to one embodiment of the present invention, the external I/O pad 461 inputs data and a control signal via the data input/output buffer 456 to the command interface 457 and the column control circuit 459. Based on the control signal and data, the state machine 458 controls the column control circuit 459, the row control circuit 403, the source line control circuit 454, and the P well control circuit 455. The state machine 458 outputs, to the column control circuit 459 and the row control circuit 403, access information to a memory cell of the memory cell array 451. Based on the access information and data, the column control circuit 459 and the row control circuit 403 controls the sense amplifier 402 and the selection circuit 460 to cause the memory cell to be active, thereby performing reading, writing, or erasure of the data. Each of the sense amplifiers 402 connected to the bit line respectively of the memory cell array 451 loads the data to the bit line or detects the potential of the bit line and retains the data by a data cache. The data from the memory cell read by the sense amplifiers 402 controlled by the column control circuit 459 is outputted to the external I/O pad 461 via the data input/output buffer 456. The selection circuit 460 selects, from among a plurality of data caches constituting the sense amplifier, a data cache connected to the bit line.

Conventionally, when a plane is not dual-partitioned and, single end S/As are used and a pad section is positioned at a chip end, line lengths of data output lines which have output information of page buffers of respective planes, have been provided with substantially the same line length. This also applies to a case where shared S/As are used for sense amplifiers. However, when a divided cell array is used in order to cope with a higher capacity in the future, a problem is caused in a data output wiring when a pad section is provided at a chip end as in the conventional case. Even when a plane is not dual-partitioned, if a configuration of sense amplifiers at both sides of a plane which is expected to be used in the future for the purpose of improving a processing speed is used, the placement of the pad section at a chip end causes the problem in a data output wiring.

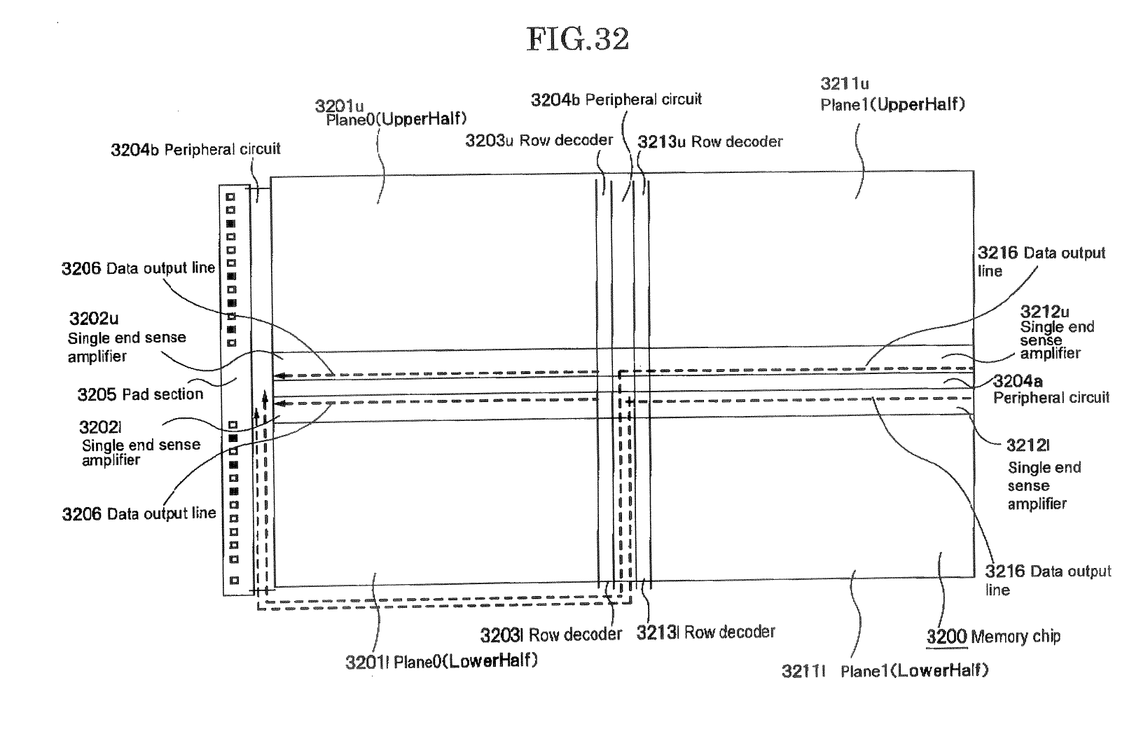

FIG. 32 shows an example where two planes are placed at left and right sides of a chip 3200 as in FIG. 1 and each of the planes is dual-partitioned to provide planes 3201U, 3201L, 321l, and 3211L. A pad section 3205 is provided at a chip end and a peripheral circuitry 3204b is provided to have a contact with the pad section. The peripheral circuitry 3204b is also provided on the chip long side center line that intersects with the chip short side center line having thereon a peripheral circuitry 3204a. The respective planes correspond to single end S/As 3202U, 3202L, 3212U and 3212L and row decoders 3203U, 3203L, 3213U and 3213L provided to surround the respective planes. As an example of a data output wiring in this case, a data output wiring 3216 having page buffer output information from the planes 3211U and 3211L may be wired while bypassing a core. However, this core bypass wiring causes the wiring length of the data output wiring 3216 to be two times or more longer than the wiring length of the data output wiring 3206 having page buffer output information from the planes 3201U and 3201L to cause a problem of skew due to different CR delay times, which hinders a high speed. When a CR delay of a simple wiring is calculated in the case of this bypass wiring, this bypass wiring causes a serial system delay of 14 ns as shown in Table 1. This bypass wiring also requires a space for a bypass wiring on a chip and this causes an increased chip size that contradicts the demand for a smaller chip packaging area.

TABLE 1

| | WireRC | redrive | RC | reciprocation ×2 |
|---|---|---|---|---|
| circumvention | 6.5 ns | 0.6 ns | 7.1 ns | 14.2 ns |
| PB penetration | 1.5 ns | 0.6 ns | 2.0 ns | 4.1 ns |

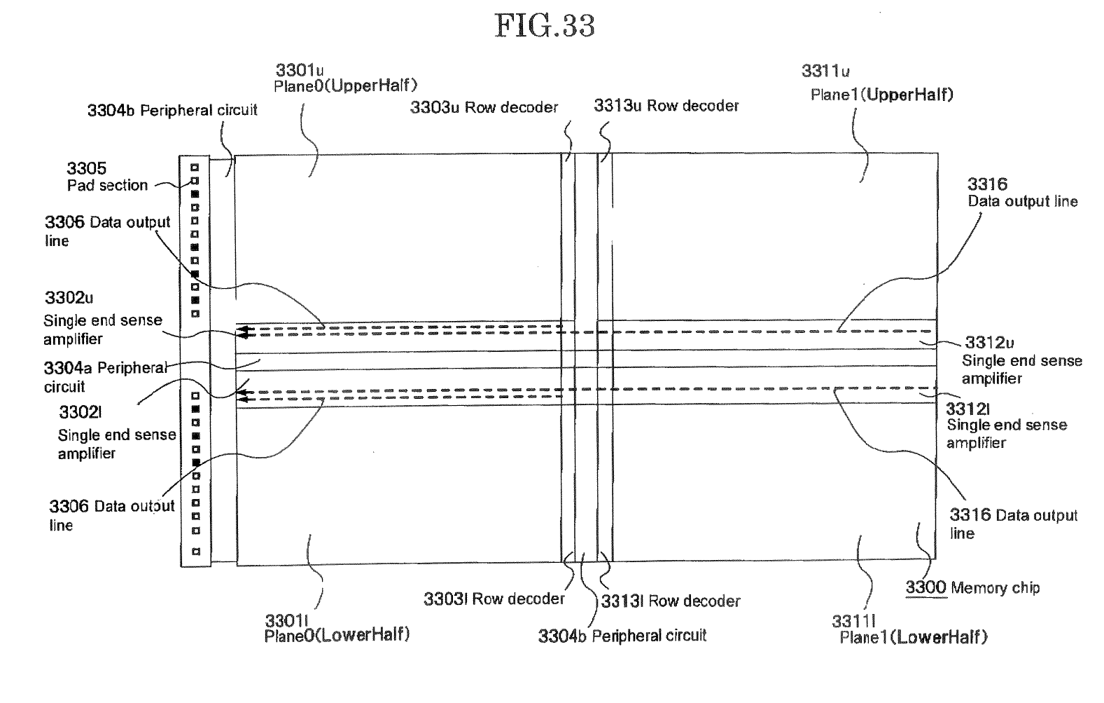

In order to satisfy the demand for a smaller chip packaging area, as a means for preventing the above core bypass wiring, when a pad section is provided at a chip end, a PB penetration wiring shown in FIG. 33 may be considered. In FIG. 33, the structures of planes 3301U, 3301L, 3311U and 3311L provided on a chip 3300 and the layout of a pad section 3305, peripheral circuitries 3304a and 3304b, single end S/As 3302U, 3302L, 3312U, and 3312L, and row decoders 3303U, 3303L, 3313U and 3313L are the same as that of FIG. 32.

The PB penetration wiring is a method by which, in order to maintain a wide wiring width of the data output wiring 3316 from the planes 3311U and 3311L, a wiring region is provided not only on one layer but also among many layers. Specifically, the PB penetration wiring is a method by which the data output wiring 3316 having page buffer output information from the planes 3311U and 3311L and the data output wiring 3306 having page buffer output information from the planes 3301U and 3301L are multi-stratified. However, this wiring also causes the data output wiring 3316 to have a wiring length two times or more long than that of the data output wiring 3306. When a CR delay of a simple wiring is calculated, delay is caused in a 4 ns serial system as shown in Table 1.

In contrast with these methods, a pad section placed on the chip long side center line allows data wirings having page buffer output information from the respective planes as shown in FIG. 1 to be substantially equal and the wiring to the pad region can be performed with the minimum distance.

In order to cope with the configuration of sense amplifiers at both sides of a plane that is expected to be used in the future for the purpose of improving a processing speed, the placement of the pad section at the chip end causes a problem in a data output wiring even when a plane is not dual-partitioned. The configuration of sense amplifiers at both sides of a plane is a method that will attract attention because two sense amplifiers placed at both sides of each plane allow the respective amplifiers share bit lines and thus a processing speed can be improved.

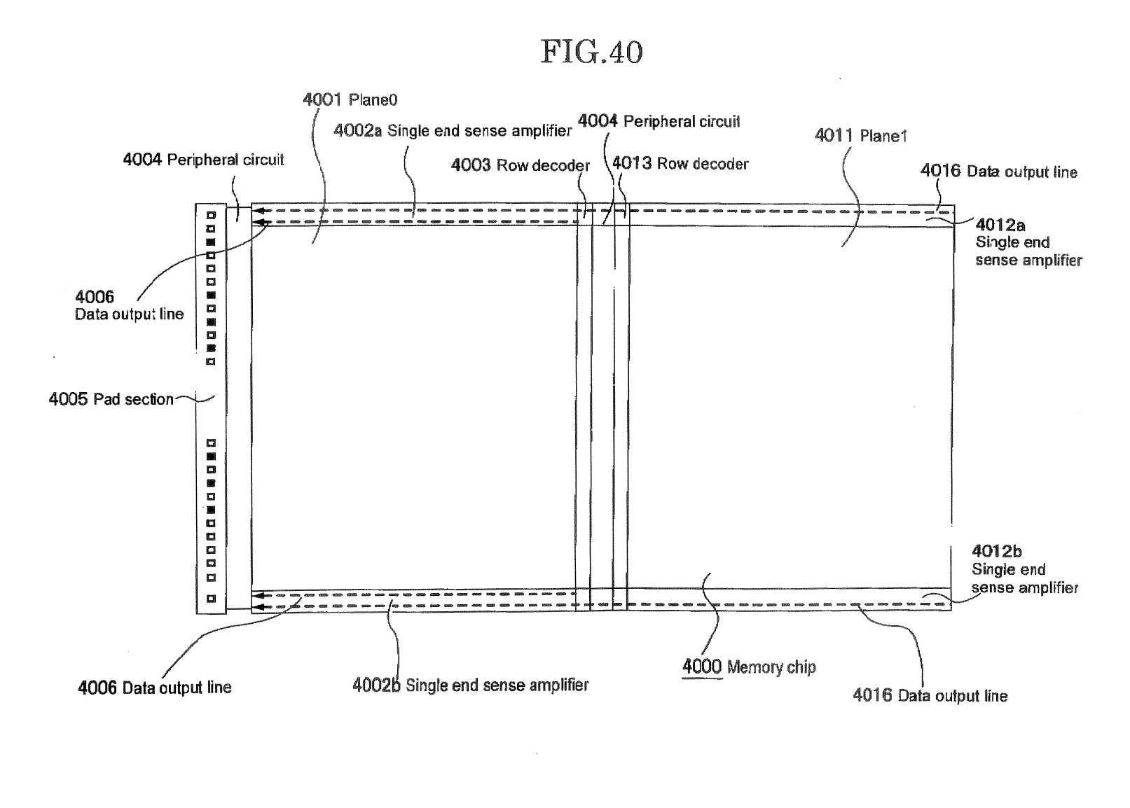

FIG. 40 shows a layout where pads are placed at a chip end that uses the configuration of sense amplifiers at both sides of a plane. A plane 0 (4001) and a plane 1 (4011) are placed at left and right sides of the chip long side center line of a memory chip 4000 and upper and lower sides of the respective planes have single end S/As 4002a, 4002b, 4012a, and 4012b, respectively. A peripheral circuitry 4004 is provided on the chip long side center line so as to be adjacent to a pad section 4005. The peripheral circuitry 4004 on the chip long side center line is sandwiched by row decoders 4003 and 4013. The pad section 4005 is placed at a chip end. Thus, a data output line 4006 from the plane 0 (4001) and a data output line 4016 from the plane 1 (4011) have different wiring lengths, causing a CR delay.

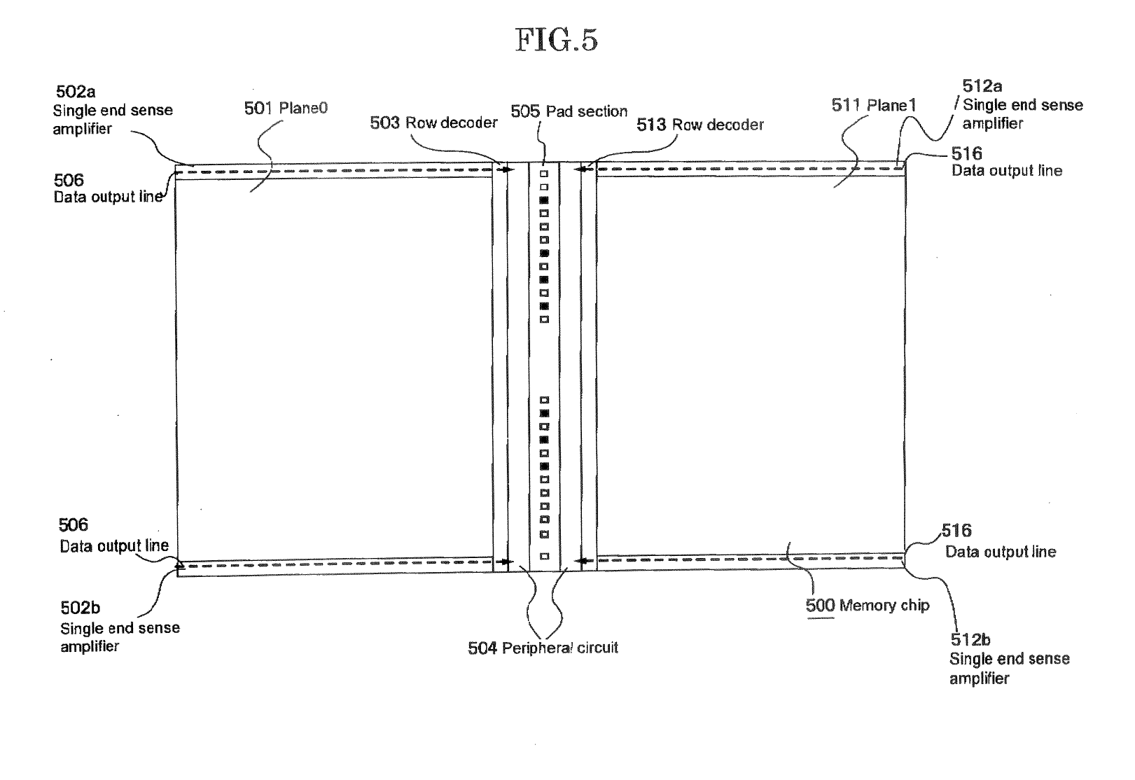

FIG. 5 illustrates an example of data wiring when two planes are used, the configuration of sense amplifiers at both sides of a plane is used, and a pad section is placed on the chip long side center line. A pad section 505 is placed on the chip long side center line of a memory chip 500. The pad section is sandwiched by peripheral circuits 504 and row decoders 503 and 513 at left and right sides. Both sides thereof have a plane 0 (501) and a plane 1 (511). Upper and lower sides of the respective planes have single end S/As 502a, 502b, 512a, and 512b. In this case, data output lines 506 and 516 from the respective planes are substantially equal and a wiring to a pad arrangement region can be achieved by the minimum distance. Thus, when the configuration of sense amplifiers at both sides of a plane is used, a pad section can be advantageously placed on the chip long side center line or on the chip short side center line in consideration of a CR delay.

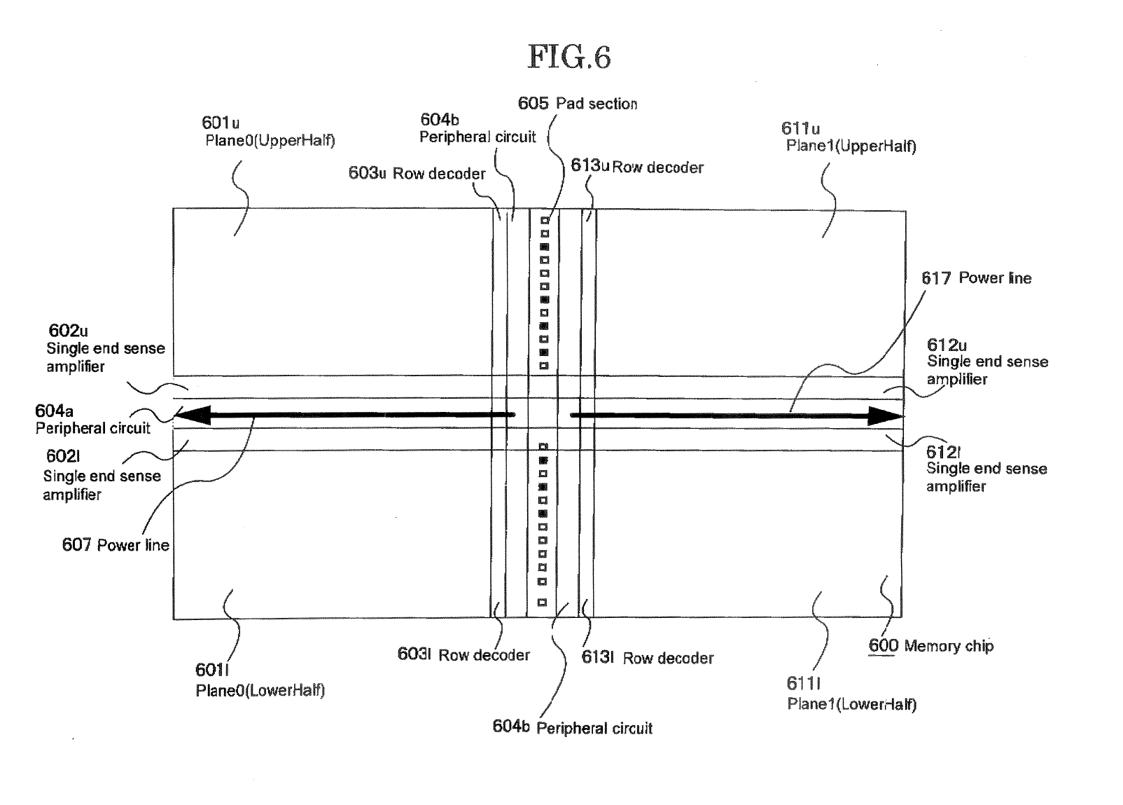

Next, a power wiring to the respective chips in the present invention will be described. FIG. 6 is a schematic view of a layout of power sources to the respective chip sections of a NAND-type flash memory which has a pad section is placed on the chip long side center line when each of two planes is dual-partitioned to upper and lower parts. Each of two planes placed on a chip 600 is divided to provide planes 601U, 601L, 611U, and 611L. A pad section 605 including a power source pad is placed on the chip long side center line. Peripheral circuitries 604b are placed at left and right sides of the pad section 605. The peripheral circuitries 604b intersect with a peripheral circuitry 604a placed on the chip short side center line. The respective planes are surrounded by single end S/As 602U, 602L, 612U, and 612L and row decoders 603U, 603L, 613U, and 613L. The respective planes are supplied with power from power lines composed of a power line 607 for supplying power to planes 601U and 601L and a power line 617 for supplying power to planes 611U and 611L that are wired from the pad section 605 including the power pads to the chip end. By placing the pad section on the chip long side center line as described above, the power lines 607 and 617 can be distributed by the minimum distance. Thus, when a fixed IR drop is assumed, power line widths can be minimized.

When a plane is not dual-partitioned and single end S/As are used to place a pad section at a chip end in a conventional case, power lines are wired from the pad section placed at the chip end to each plane by a minimum distance. Thus, the widths of power lines could be minimized. This also applies to a case where shared S/As are used as sense amplifiers. However, when divided cell arrays are used in order to cope with an increased capacity in the future, the conventional layout of a pad at a chip end causes a problem in a data output wiring.

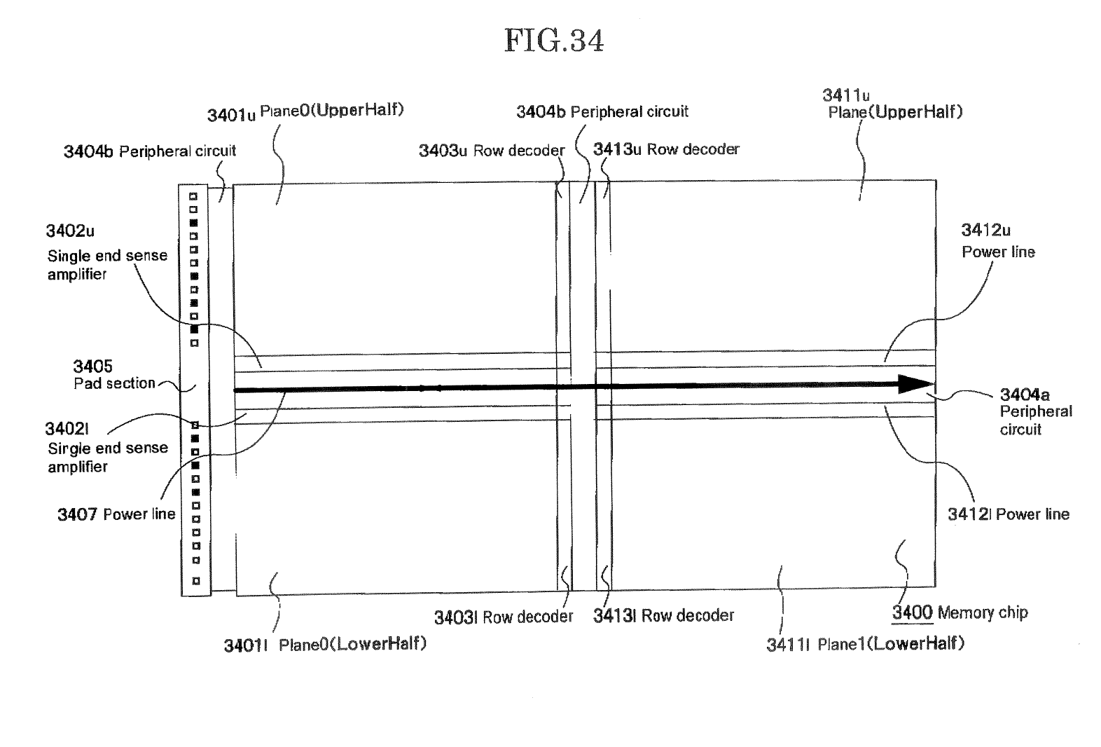

FIG. 34 is a schematic view of a power source layout when each of the above two planes is dual-partitioned to upper and lower parts and a pad section is placed at a chip end. Each of two planes placed on a memory chip 3400 is dual-partitioned to upper and lower parts to provide planes 3401U, 3401L, 3411U, and 3411L. A pad section 3405 is placed at a chip end and a peripheral circuitry 3404b is placed to have a contact with a pad section. The peripheral circuitry 3404b is also placed on the chip long side center line that intersects with the chip short side center line on which the peripheral circuitry 3404a is placed. The respective planes correspond to single end S/As 3402U, 3402L, 3412U, and 3412L and row decoders 3403U, 3403L, 3413U, and 3413L provided to surround the respective planes. As shown in FIG. 32 and FIG. 33, a core bypass wiring or a PB penetration wiring may be considered as a data output wiring in this case. However, with respect to a power wiring, one power line 3407 is placed on the chip short side center line from the pad section 3405 including a power source pad placed at an end of the chip 3400 to planes 3401U, 3401L, 3411U, and 3411L. In this case, a wiring from the chip end formed the power pad to a chip end at an opposite side is required to cause an increased wiring distance. Thus, in order to guarantee a fixed IR drop and reliability of the power line, the width of the power line must be expanded. The required power line width requires a power source for a peripheral circuitry to be wired. The required power line width requires a power source line width two times or higher than that for a case where a pad section is placed on the chip long side center line because wiring power line for peripheral circuits is required, thus causing an increased chip size.

The present invention can provide a nonvolatile semiconductor memory device in which a wiring specific resistance that increases with an increase of a wiring length and with a decrease of a wiring width can be minimized for the same wiring width. The present invention also can provide a nonvolatile semiconductor memory device in which a wiring width is minimized when a specified IR drop is assumed.

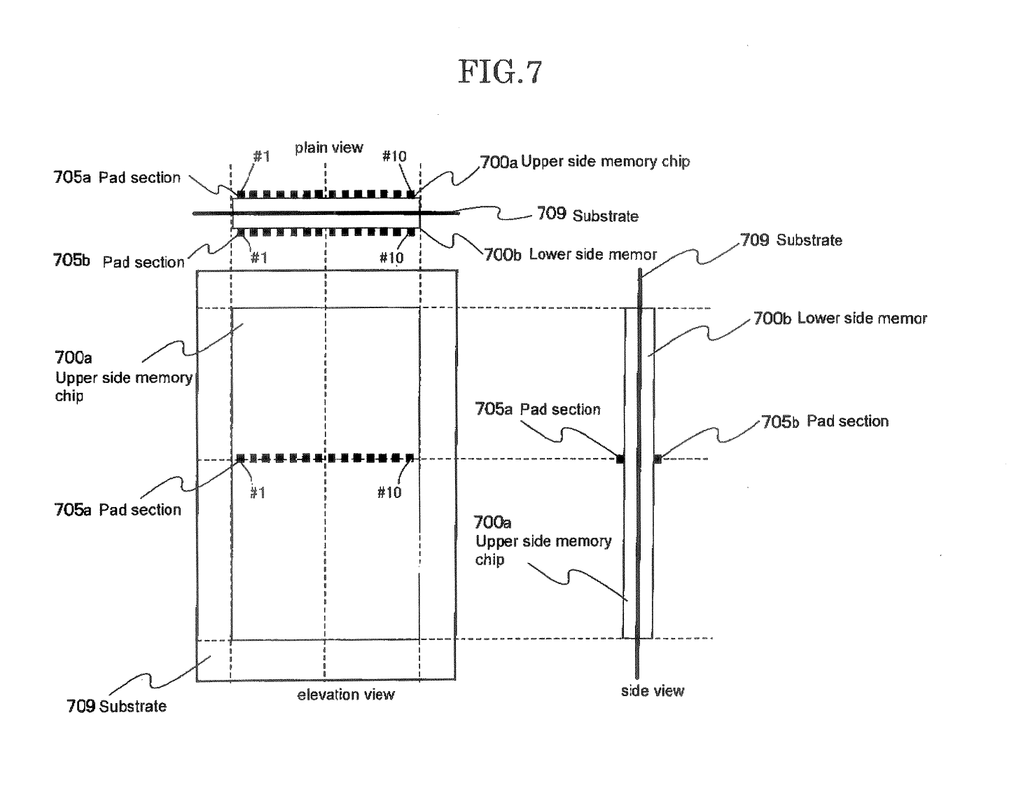

Next, the structure of layered chips according to the nonvolatile semiconductor memory device according to the present invention will be described with reference to FIG. 7 when a package having layered chips is used in order to cope with a higher capacity.

In FIG. 7, a substrate or a lead frame 709 has thereon layered chips (upper side) 700a according to the present invention in which pad sections are provided on the chip long side center line and layered chips (lower side) 700b having the same structure so that the layered chips (upper side) 700a and the layered chips (lower side) 700b are adhered back-to-back to one another. Pads are placed in a symmetric manner to sandwich a line connecting intermediate points of two short sides of the substrate. Thus, pad sections 705a and 705b are placed on a single line even after the adhesion of top and back faces of chips. Thus, top faces and back faces can be similarly bonded. This eliminates a need for changing the positions of pads of the chip 700a set at the upper side and the chip 700b set at the lower side and thus the cost for package/chip can be reduced.

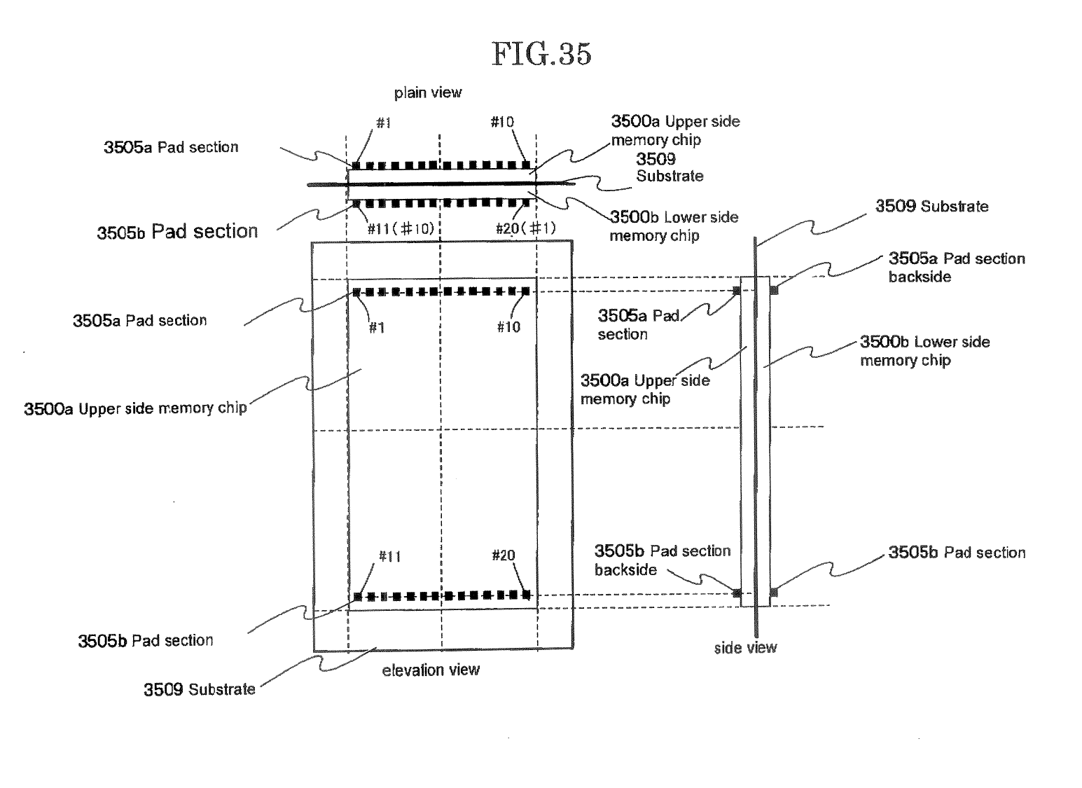

In contrast with this, FIG. 35 shows the layered structure of a nonvolatile semiconductor memory device in which a pad section is placed at a chip end. When the chips 3500a and 3500b in which pad sections are placed at chip ends are adhered back-to-back to a substrate or a lead frame 3509, pads at the upper side are dislocated from those at the lower side. Thus, a conventional design has required, in order to align the pad positions, the pad position of a chip 3500a set at the upper side and the pad position of a chip 3500b set at the back side to be changed. Specifically, the conventional design requires two types of chip pad positions #1 to #10 set at the upper side and chip pad positions #11 to #20 set at the lower side. This is a cause of an increased cost.

According to the present invention, the need to change pad positions of chips set at a top face and chips se at a back face during the above chip layering operation is eliminated and the same chips can be adhered. Thus, an increased cost can be prevented.

### EMBODIMENT 1

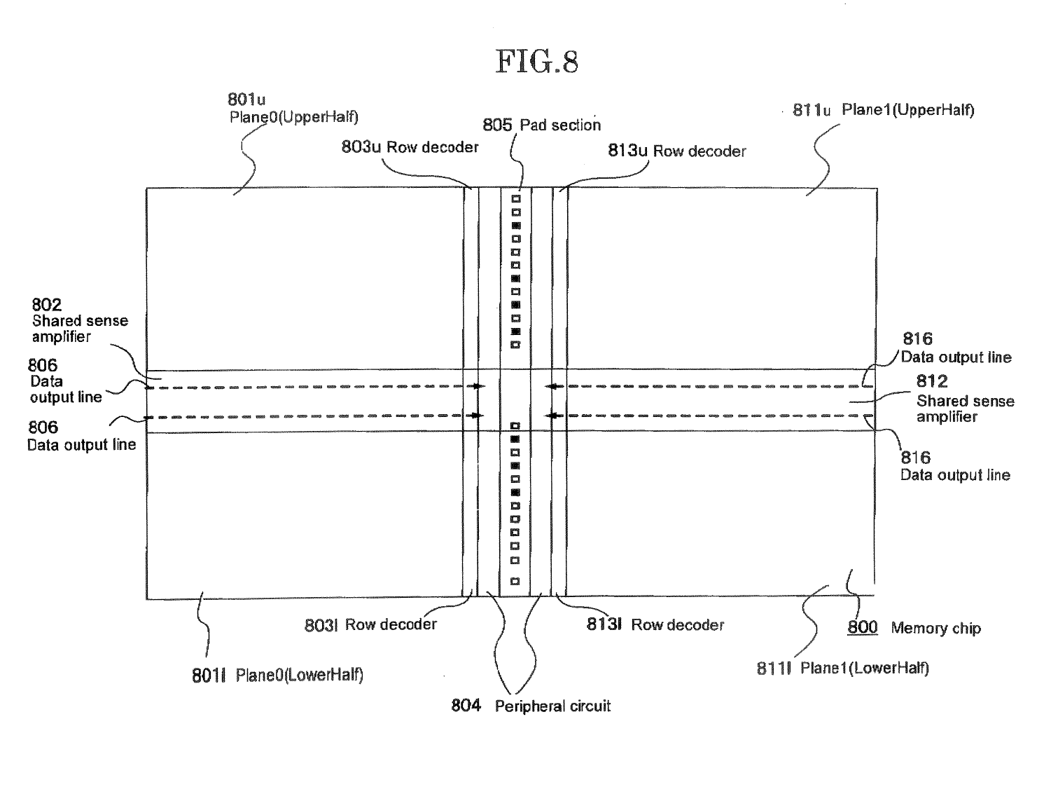

In Embodiment 1, there are two planes. Each of two planes is dual-partitioned and a pad section is placed on the chip long side center line and shared sense amplifiers (shared S/As) are used as sense amplifiers. FIG. 8 is a schematic view of a chip layout of a NAND-type flash memory, according to one embodiment of the present invention, which has the same plane layout as that of FIG. 1 and shared sense amplifiers (shared S/As) are used as sense amplifiers and a pad section is placed on the chip long side center line. A memory chip 800 has thereon two planes (cell arrays) placed at left and right sides. The respective planes are dual-partitioned to upper and lower parts to provide planes 801U, 801L, 811U, and 811L. A pad section 805 is placed on the chip long side center line that is sandwiched between peripheral circuitries 804 the left and right sides thereof. The respective planes have corresponding shared sense amplifiers (shared S/As) 802 and 812 and row decoders 803U, 803L, 813U, and 813L. To the pad section 805 placed on the chip long side center line, data output lines 806 are wired that have output information of a cell data rewriting/reading circuit (hereinafter page buffer) from the planes 801U and 801L respectively. Similarly, a data output lines 816 having page buffer output information of the planes 811U and 811L respectively are also wired to the pad section 805. In this case, the pad section 805 is placed on the chip long side center line and thus the data output wirings 806 and 816 can have a substantially equal wiring length.

Conventionally, when a plane is not dual-partitioned, even when shared S/As are used as sense amplifiers instead of single end S/As, a pad section placed at a chip end could has allowed data output lines having page buffer output information of the respective planes to have a substantially equal line length. Even when a pad section is placed at an end of a chip long side or at an end of a chip short side, data output lines having page buffer output information of the respective planes could have a substantially equal line length regardless of a direction along which the pad section is placed. However, when divided cell arrays are used in order to cope with a higher capacity in the future, the conventional placement of a pad section at a chip end causes a problem in a data output wiring.

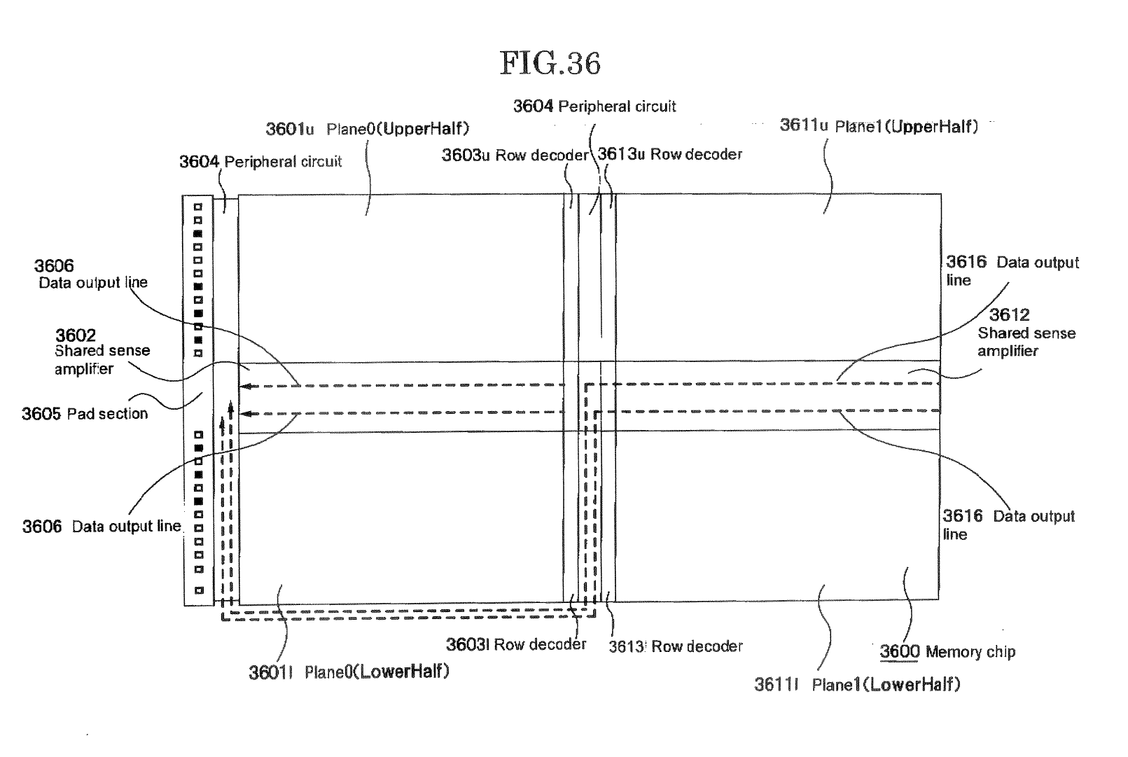

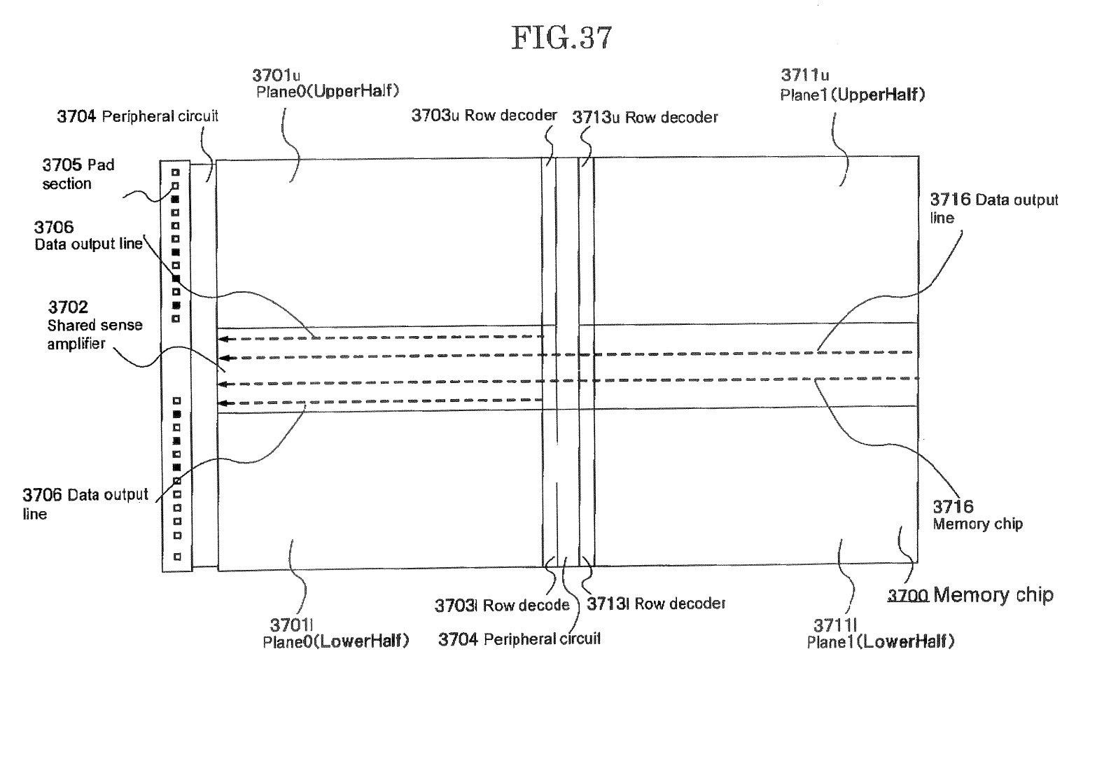

FIG. 36 illustrates an example of a core bypass wiring when a pad section is placed at a chip end and shared S/As are used as in FIG. 32. FIG. 37 illustrates an example of a PB penetration wiring when a pad section is placed at a chip end and shared S/As are used as in FIG. 32. A data output wiring does not change even if shared S/As are used instead of single end S/As. Thus, the wirings as in FIG. 32 and FIG. 33 are required. These methods cannot provide data output lines 3606 and 3616 with a substantially equal data wiring length as those of data output lines 3706 and 3716. Thus, these methods have different data wiring lengths and thus cannot solve the problem of skew due to CR delay. Thus, as shown in Table 1, 14ns of CR delay is caused in FIG. 36 and 4ns of CR delay is caused in FIG. 37. The PB penetration wiring of FIG. 37 can provide an improved CR delay compared with a case of the core bypass wiring of FIG. 36 but requires, when compared with a case where a pad section is placed on the chip long side center line, a wider wiring width for an assumed specified IR drop. Thus, the PB penetration wiring of FIG. 37 cannot satisfy the demand for a downsized chip.

In contrast with these methods, if a pad section is placed on the chip long side center line, data wirings having page buffer output information from the respective planes can have a substantially equal length and can be wired to a pad region with the minimum distance as shown in FIG. 8.

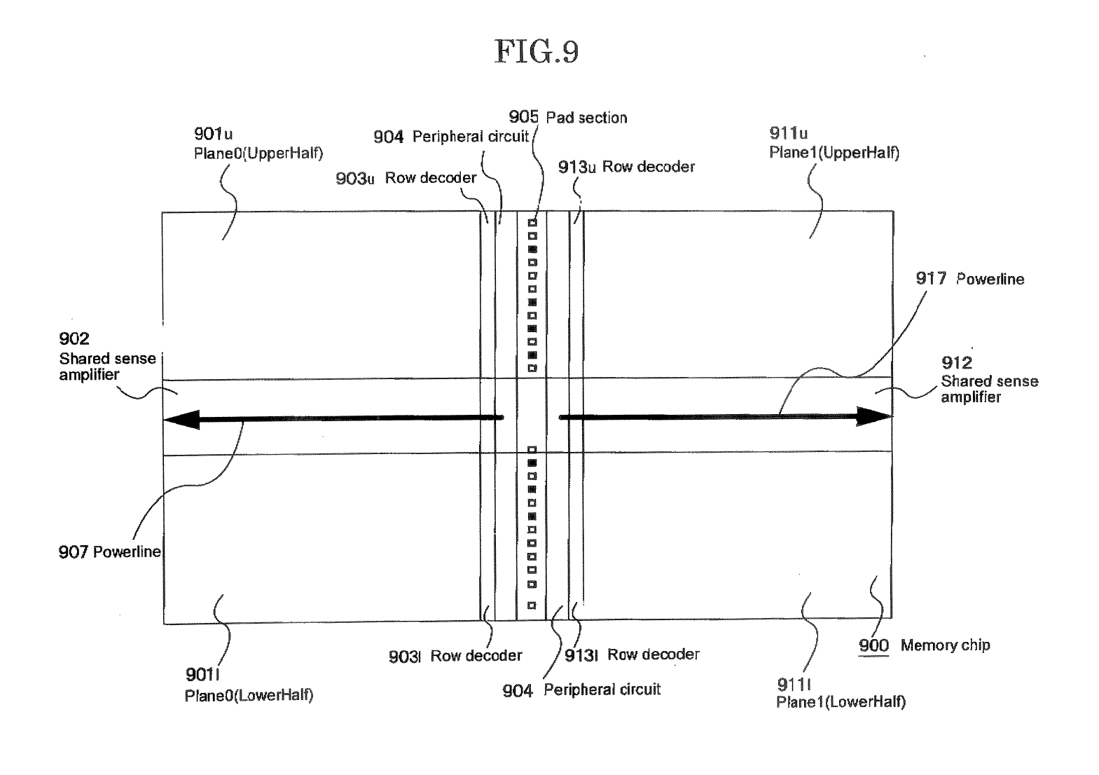

Next, power wirings to the respective chips in a NAND-type flash memory which has the same plane layout as that of FIG. 1 is used, shared sense amplifiers (shared S/As) are used as sense amplifiers, and a pad section is placed on the chip long side center line according to one embodiment of the present invention will be described with reference to FIG. 9. A pad section 905 including power pads is placed on the long side center line of a chip 900. The respective planes are supplied with power by a power line 907 for supplying power to planes 901U and 901L and a power line 917 for supplying power to planes 911U and 911L that are wired from the pad section 905 including the power pads to a chip end By placing the pad section on the chip long side center line as described above, the power source lines 907 and 917 can be distributed with the minimum distance.

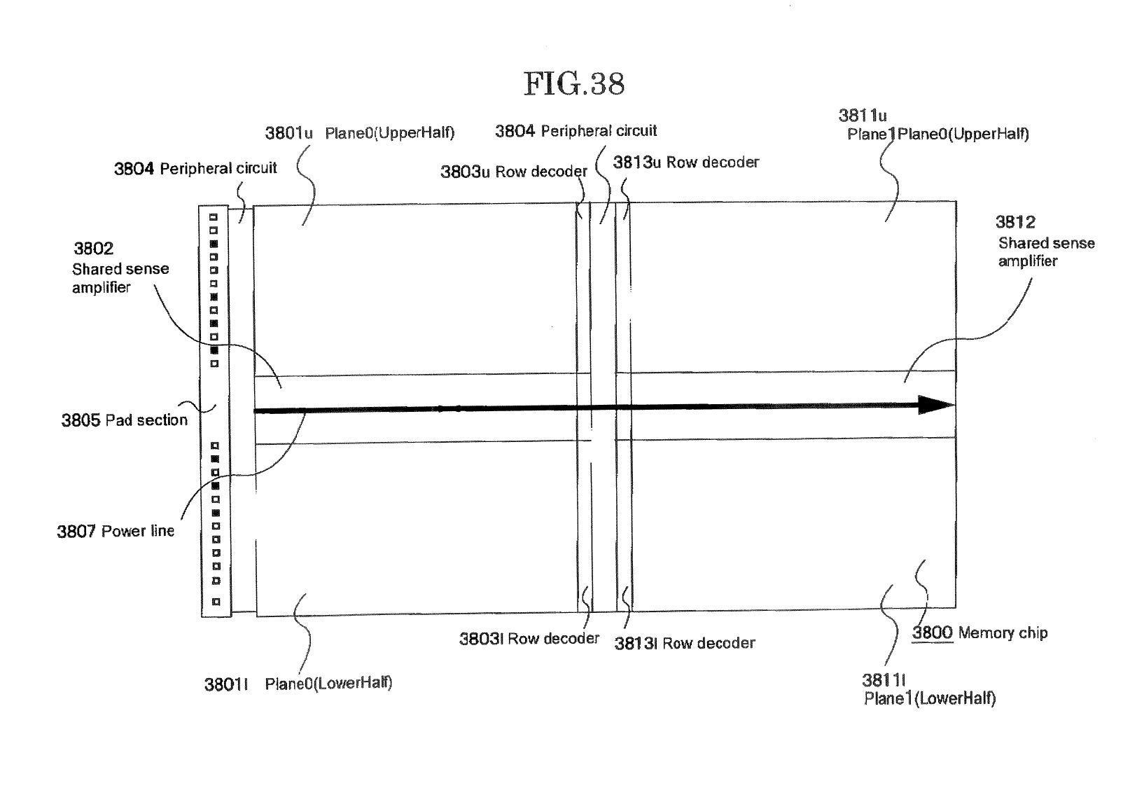

FIG. 38 is a schematic view of a power source layout in the same plane layout as the above one. In FIG. 38, a shared sense amplifier (shared S/A) is used as a sense amplifier and a pad section is placed at a chip end. This case also causes no change in the power source wiring as in FIG. 34 using single end S/As even if a core bypass wiring or a PB penetration wiring is used as a data wiring. Thus, a power line 3807 is wired from an end of a chip 3800 formed power pads to a chip end at an opposite side. In this case, a wiring distance is increased compared with a case of FIG. 9. Thus, in order to guarantee a fixed IR drop and reliability of the power line, the power line must have an increased width. The required width of the power line also is required space of a power line for a peripheral circuitry to be wired. Thus, the power source requires a width two times or more high than that in the case where a pad section is placed on the chip long side center line, thus causing an increased chip size.

The present invention can provide a nonvolatile semiconductor memory device in which a wiring specific resistance that increases with an increase of a wiring length and with a decrease of a wiring width can be minimized for the same wiring width. When a specified IR drop is assumed, a nonvolatile semiconductor memory device having the minimized wiring width can be provided.

Even if shared sense amplifiers (shared S/As) are used as sense amplifiers, a pad section placed on the chip long side center line can provide the same effect by a package having layered chips for coping with a higher capacity as that in FIG. 7.

### EMBODIMENT 2

Embodiment 1 as the best mode is an embodiment in which the respective two planes are dual-partitioned. The following section will describe an embodiment of the present invention in which a further higher capacity is required and thus each of four planes is dual-partitioned to upper and lower parts or to left and right parts.

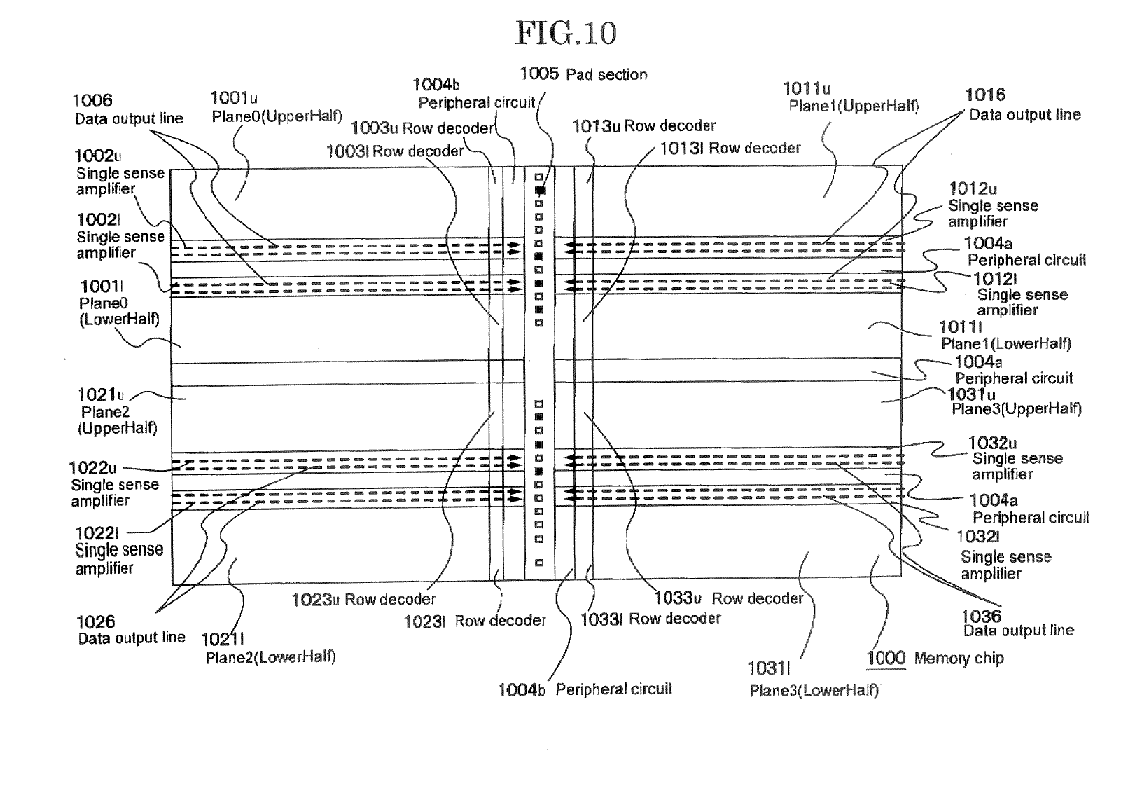

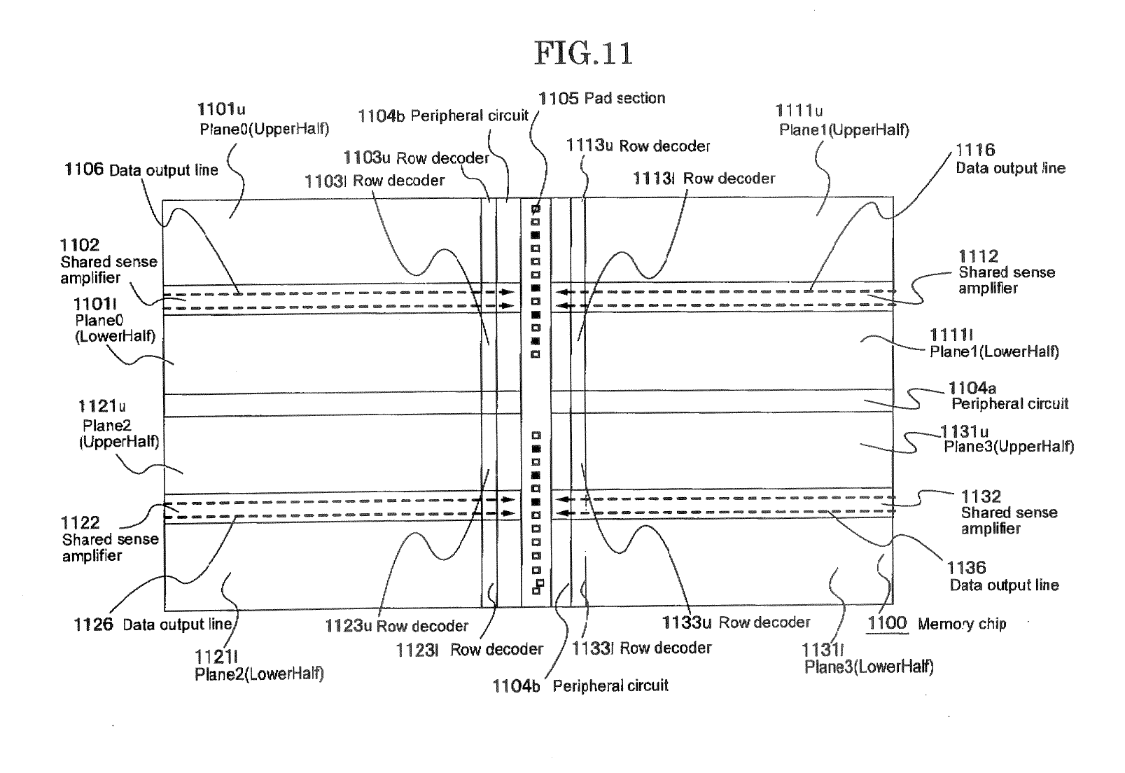

In Embodiment 2, there are four plans. The respective four planes are dual-partitioned to upper and lower parts and a pad section is placed on the chip long side center line. FIG. 10 is a schematic view of a chip layout of a NAND-type flash memory which has the respective four planes are divided to upper and lower parts, single end S/As are used, and a pad section is placed on the chip long side center line according to one embodiment of the present invention. A pad section 1005 is placed on the long side center line of a chip 1000. A data line 1006 having page buffer output information of a plane 0 and a data line 1016 having page buffer output information of a plane 1 are symmetrically arranged on a single straight line at left and right sides to sandwich a pad section 1005 placed on the chip long side center line. Data wirings 1026 and 1036 having page buffer output information of a plane 2 and a plane 3 are also similarly arranged, respectively. This provides the respective data output lines 1006, 1016, 1026, and 1036 with an equal wiring length and thus no CR delay is caused among data wirings. Thus, the present invention can provide a nonvolatile semiconductor memory device that can effectively cope with a higher capacity and an increased division number of a plane. The above effect also can be obtained in the case as shown in FIG. 11 where the same plane layout uses shared sense amplifiers as sense amplifiers.

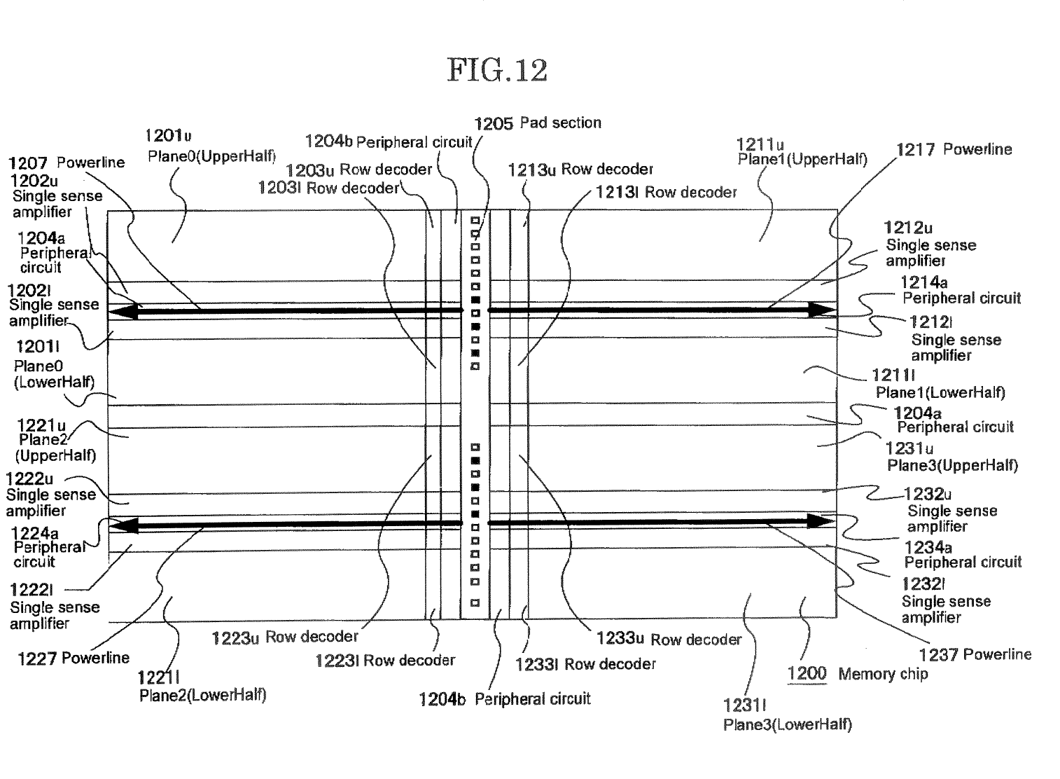

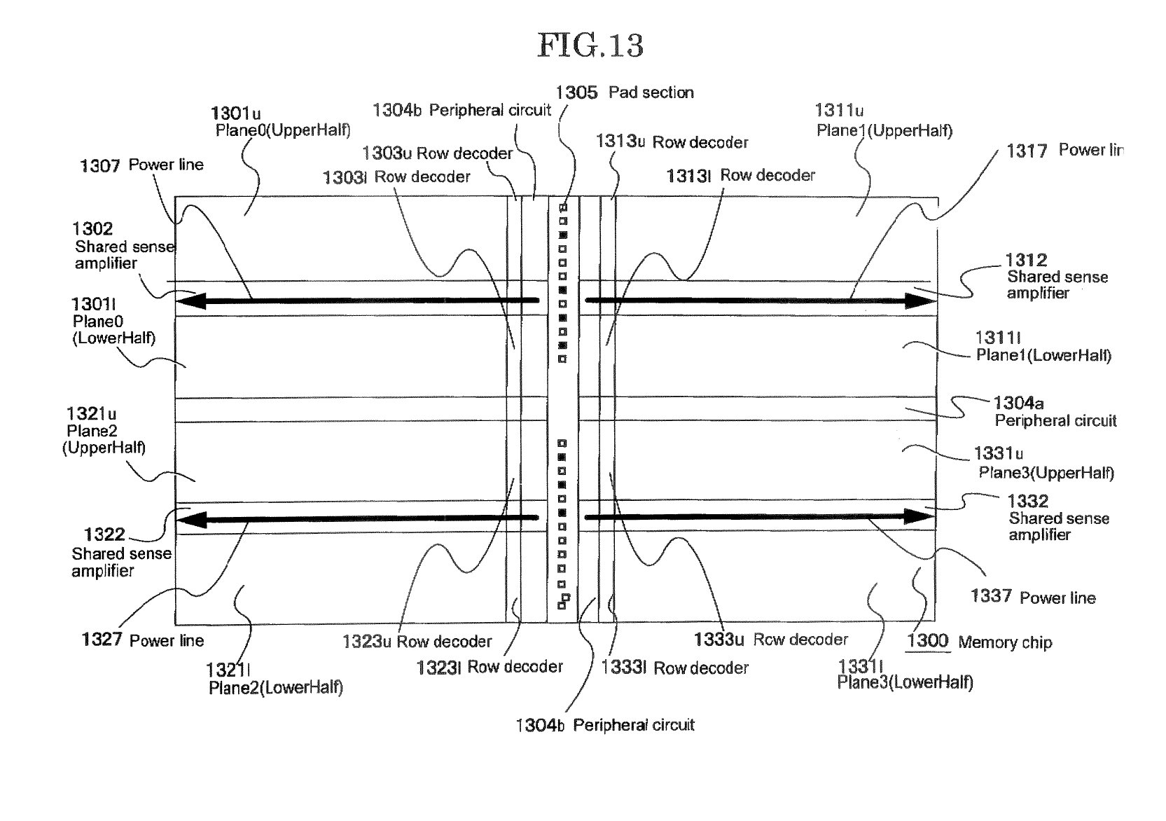

FIG. 12 illustrates a power source wiring in FIG. 10. A pad section 1205 including power pads is placed at the center of a chip 1200. Power source lines 1207, 1217, 1227 and 1237 are wired from the pad section 1205 to the respective planes. The respective wirings having the minimum length are wired to a chip end. A wiring specific resistance that increases with an increase of a wiring length and with a decrease of a wiring width can be minimized for the same wiring width. When a specified IR drop is assumed, a wiring width can be minimized. The above effect also can be obtained even in the same plane layout as shown in FIG. 13 in which shared S/As are used as sense amplifiers. It is noted that, even if the number of planes is increased, the advantage by the present invention for layering and packaging chips of a nonvolatile semiconductor memory device as shown in FIG. 7 over a nonvolatile semiconductor memory device in which a pad section is placed at a chip end can be similarly secured.

### EMBODIMENT 3

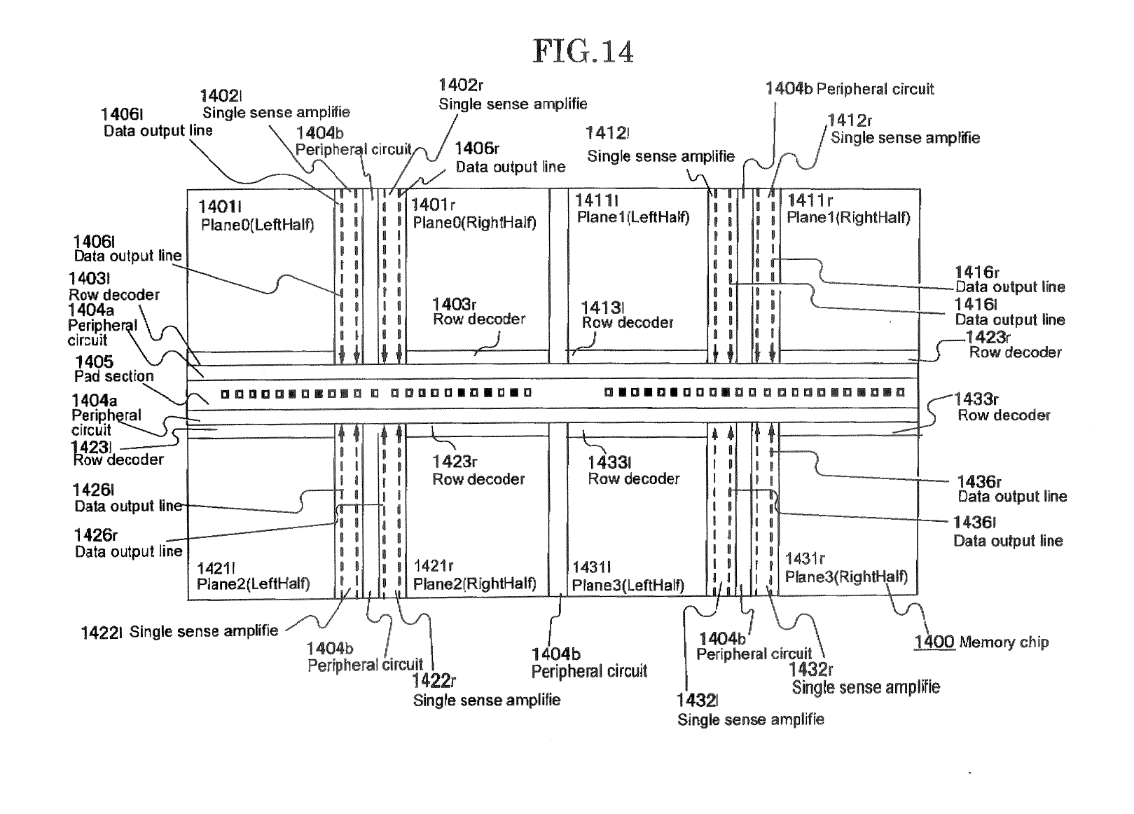

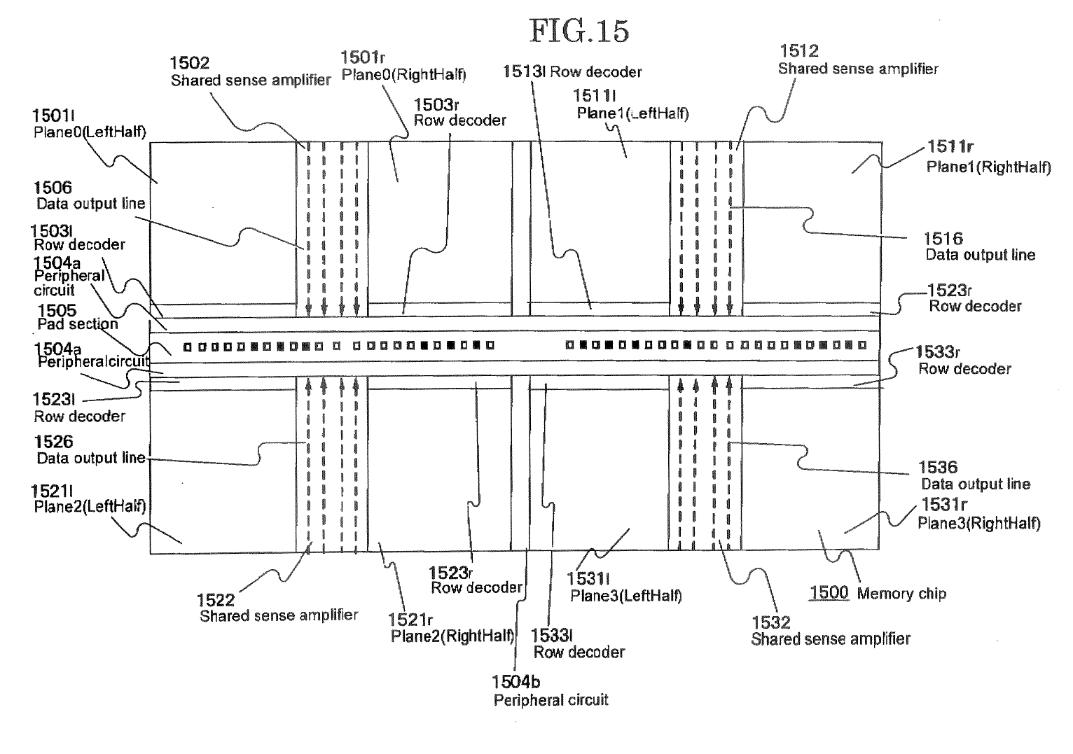

In Embodiment 3, there are four planes. The respective four planes are dual-partitioned to left and right parts and a pad section is placed on the chip short side center line. FIG. 14 is a schematic view of a chip layout of a NAND-type flash memory which has the four respective planes which are dual-partitioned to left and right parts of RightHalf and LeftHalf, single end S/As, and a pad section placed on the chip short side center line according to one embodiment of the present invention. A case may be considered in the future where a demand for a smaller packaging area requires the respective planes to be dual-partitioned to left and right parts for the convenience of a chip layout area. However, this case also may be coped with by placing a pad section on the chip short side center line. In FIG. 14, a pad section 1405 including power pads is placed on the chip short side center line on a memory chip 1400. Data output lines 1406L, 1406R, 1416L, 1416R, 1426L, 1426R, 1436L, and 1436R are wired from the respective planes with the minimum distance and the respective wiring lengths are equal, thus preventing a problem of skew. The wiring distance is minimum from the chip center part. The wiring width can be minimized when a specified IR drop is assumed. This effect can be also obtained when shared S/As are used as shown in FIG. 15.

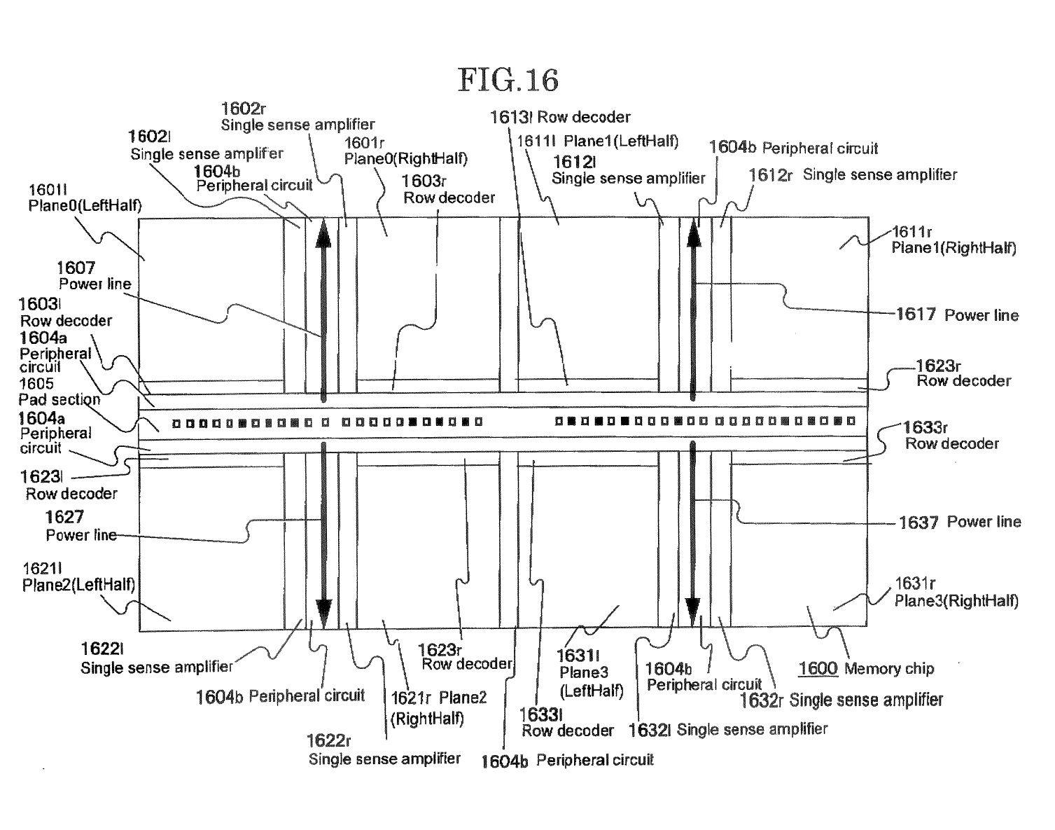

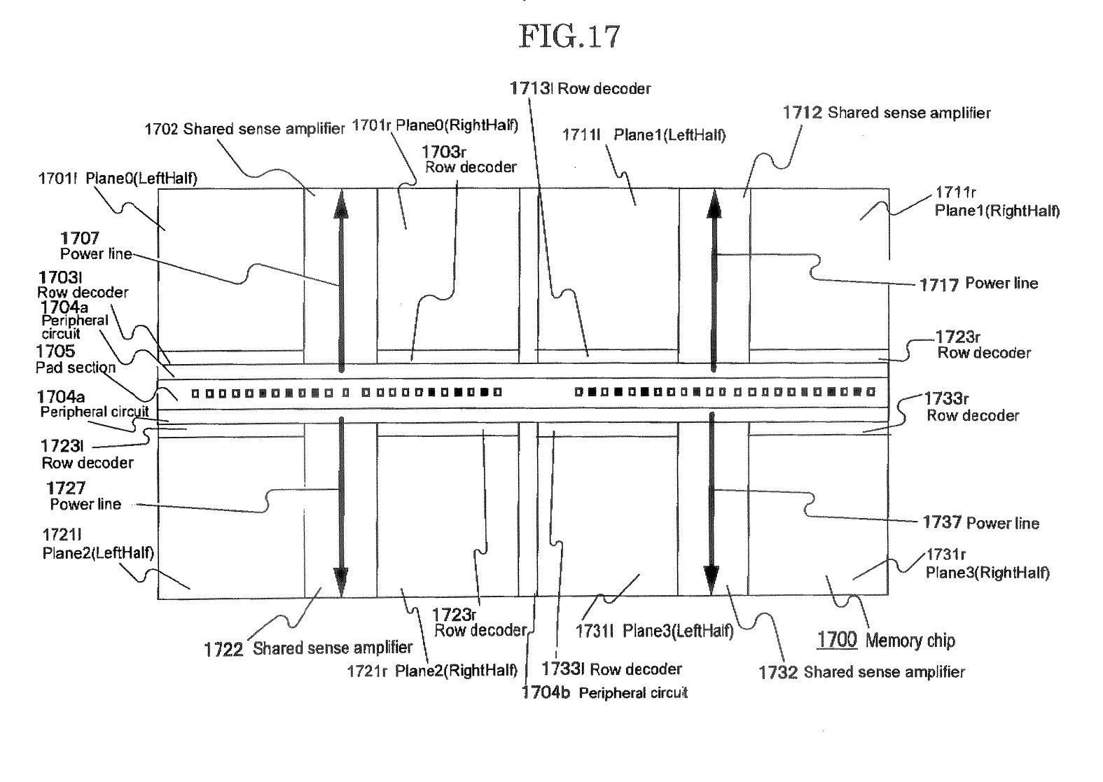

FIG. 16 is a power source wiring diagram of FIG. 14. Power lines 1607, 1617, 1627, and 1637 are wired from a pad section 1605 including power pads placed on the short side center line of a chip 1600 to the respective planes. The respective wiring lengths to the chip end are minimum. A wiring specific resistance that increases with an increase of a wiring length and with a decrease of a wiring width can be minimized for the same wiring width. The wiring width can be minimized when a specified IR drop is assumed. The above effect also can be obtained when the same plane layout uses shared sense amplifiers as sense amplifiers as shown in FIG. 17. It is noted that the advantage of the present invention can be similarly secured for a case where a pad section for layering chips is placed at a chip end as shown in FIG. 7.

When there are four planes and the respective four planes are dual-partitioned to provide eight planes, and when the planes are divided on the short side center line to upper and lower parts, a pad section is placed on the chip long side center line. When the planes are divided on the long side center line to left and right parts on the other hand, a pad section is placed on the chip short side center line. This can provide a layout minimizing the respective data wiring lengths.

### EMBODIMENT 4

In Embodiment 4, there are four planes. The respective four planes are dual-partitioned and a pad section is placed on the chip long side center line. Embodiment 4 is different from Embodiment 2 and Embodiment 3 in that a PB penetration wiring is used as a data output wiring. When the respective four planes are dual-partitioned to provide eight planes, the layout of Embodiment 2 or Embodiment 3 can minimize the respective data wiring length. However, there may be a case where the convenience of a chip packaging requires a plane to be divided on the short side center line to upper and lower parts and a pad section must be placed on the chip short side center line and a case where a plane must be divided on the long side center line to left and right parts and a pad section must be placed on the chip long side center line. In these cases, a PB penetration wiring can be additionally used to provide a layout that minimizes the respective data wirings.

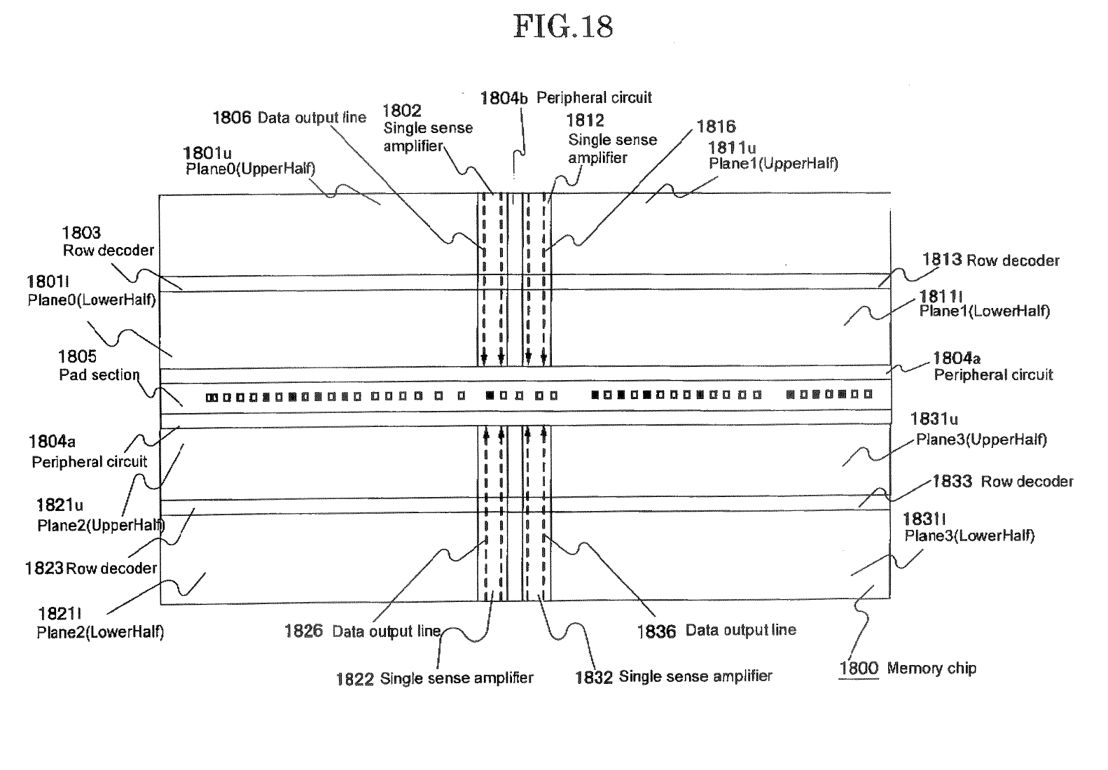

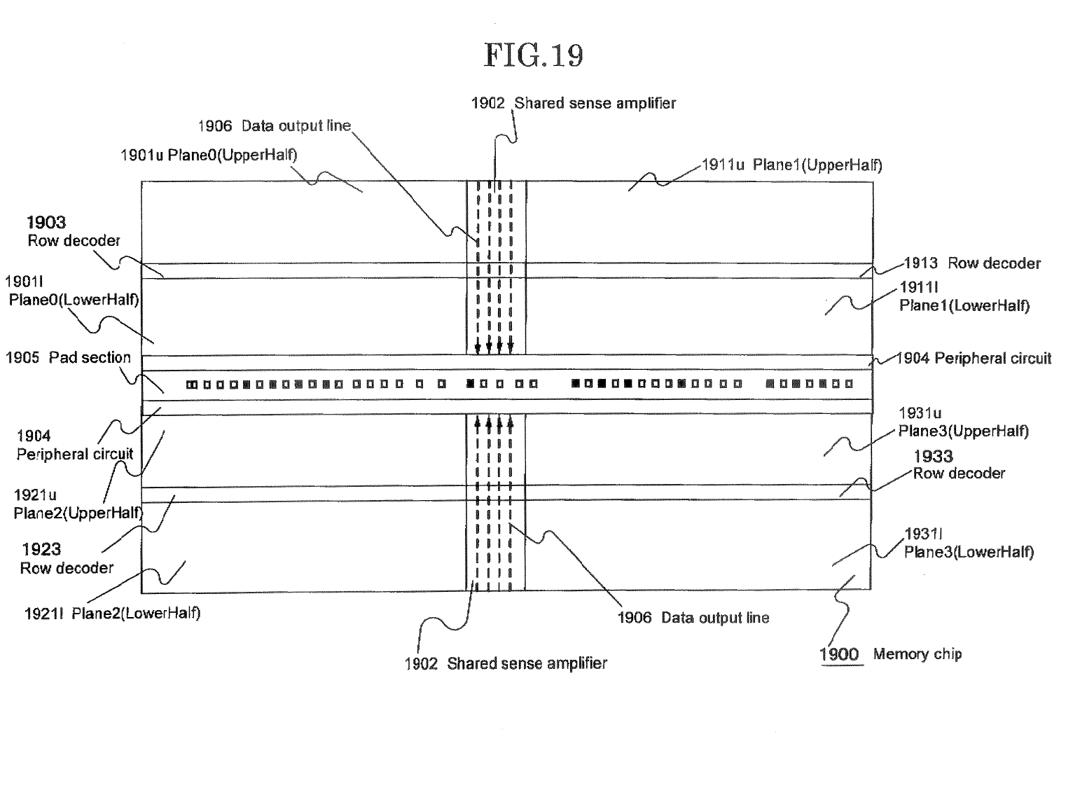

FIG. 18 is a schematic view of a chip layout of a NAND-type flash memory which has the respective four planes as in Embodiment 2 are dual-partitioned to upper and lower parts and a pad section placed on the chip short side center line according to one embodiment of the present invention. In this case, a difference from Embodiment 2 is that a PB penetration wiring must be additionally used in order to extend a data output wiring to a pad section 1805 placed on the short side center line of a chip 1800 with the minimum distanced from planes 1801U, 1811U, 1821L, and 1831L having no contact with the pad section 1805. Specifically, in this layout, in order to wire a data line 1806 from the planes 1801U and 1801L to the pad section 1805 with the minimum distance, the data line 1806 is wired parallel to a peripheral circuitry 1804b placed on the chip long side center line. However, this layout causes the wiring from the plane 1801U and the wiring from the plane 1801L to be provided at same position. Thus, the additional use of the PB penetration wiring can provide the wiring with the minimum distance. Although the different wiring lengths causes CR delay, the wiring by the minimum distance as described above can minimize the CR delay. Data output wirings 1816, 1826, and 1836 from the respective planes are also subjected to a PR penetration wiring. In the entire chip, the respective wirings 1806, 1816, 1826, and 1836 have an equal wiring length and thus CR delay can be minimized. When the same layout of planes, and when a pad section uses shared sense amplifiers as sense amplifiers, the layout will be as shown in FIG. 19. This case also requires an additional use of a PB penetration wiring and can obtain the same effect.

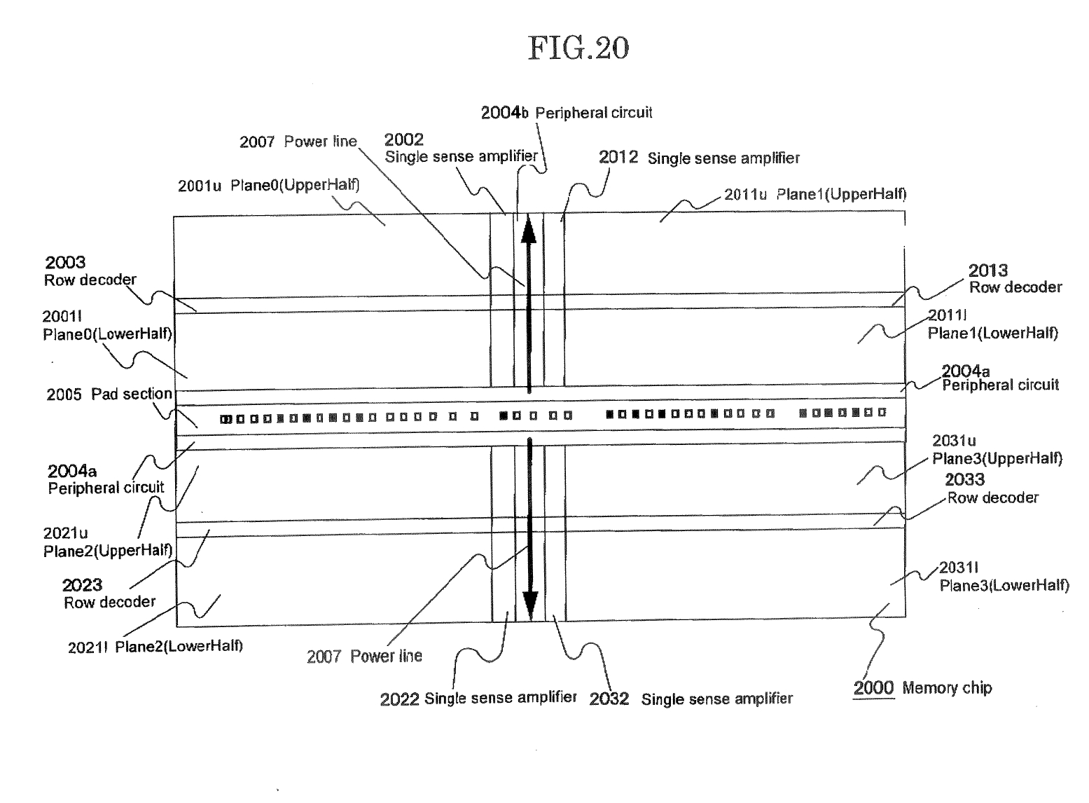

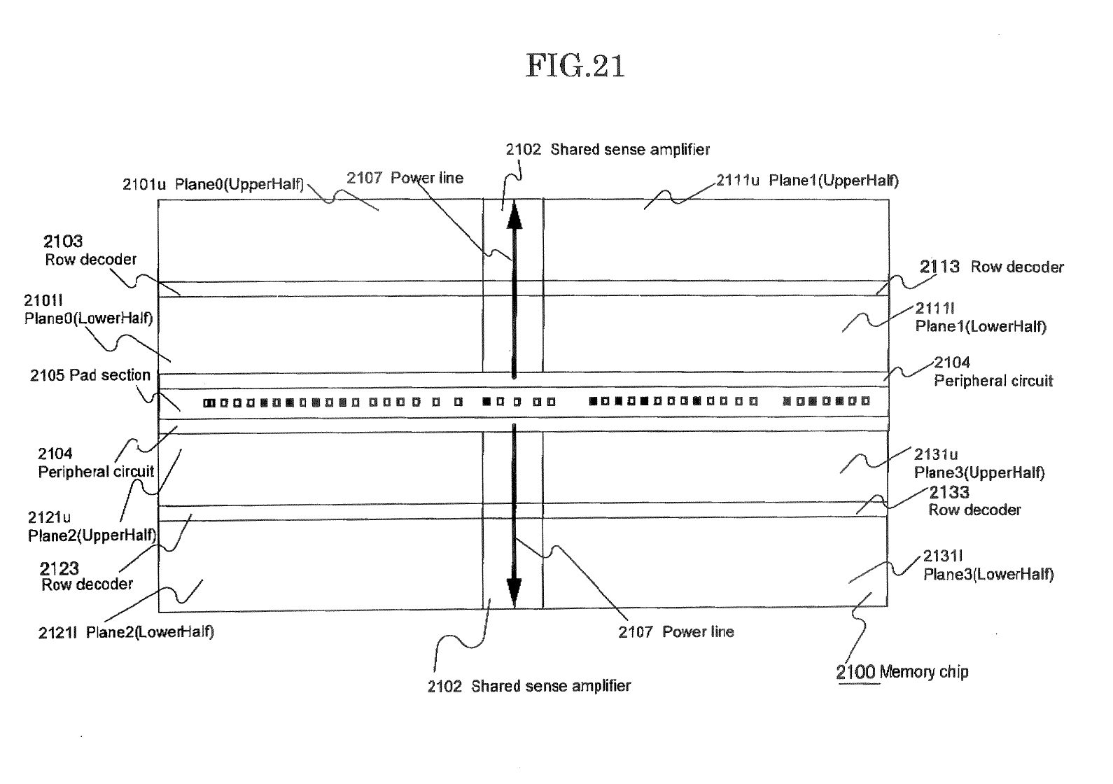

FIG. 20 illustrates a power wiring in the case of the layout of planes and pads. In this case, a power line 2007 can be wired to a chip end with the minimum distance. Thus, when a specified IR drop is assumed, a power line width can be minimized. When shared S/As are used as sense amplifiers, the layout as shown in FIG. 21 is obtained and the same effect can be obtained. The advantage of package/cost also can be secured in consideration of a lamination layer as in FIG. 7.

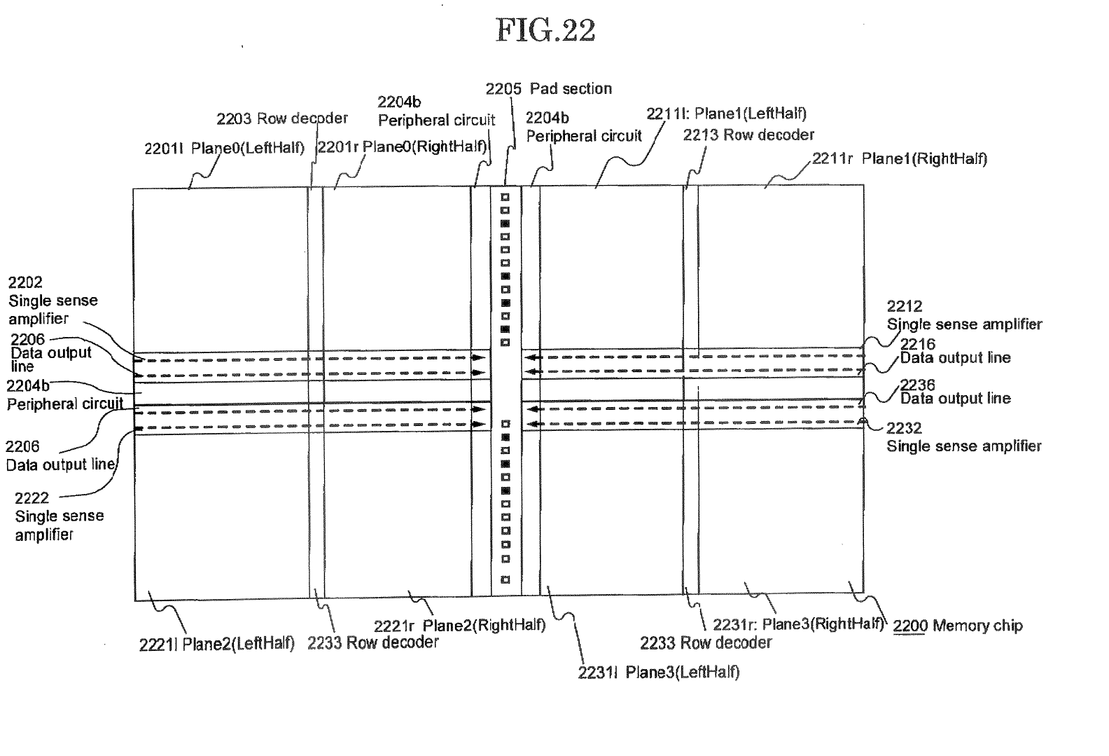

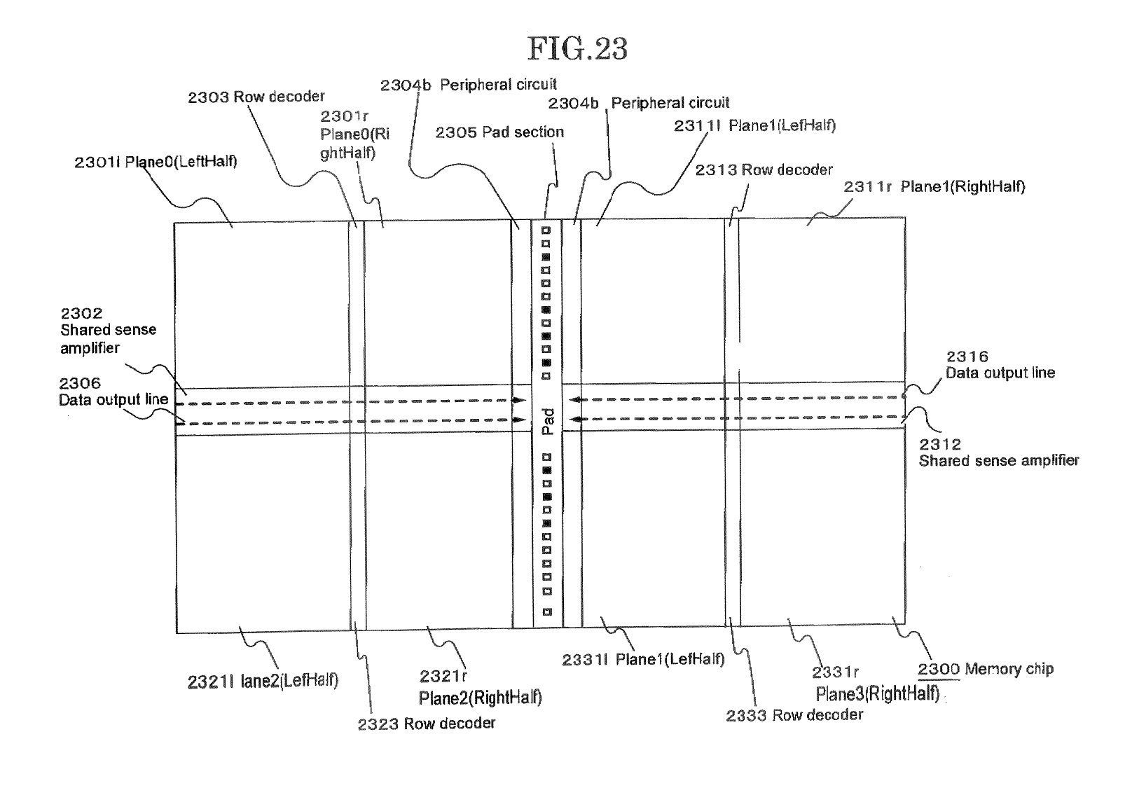

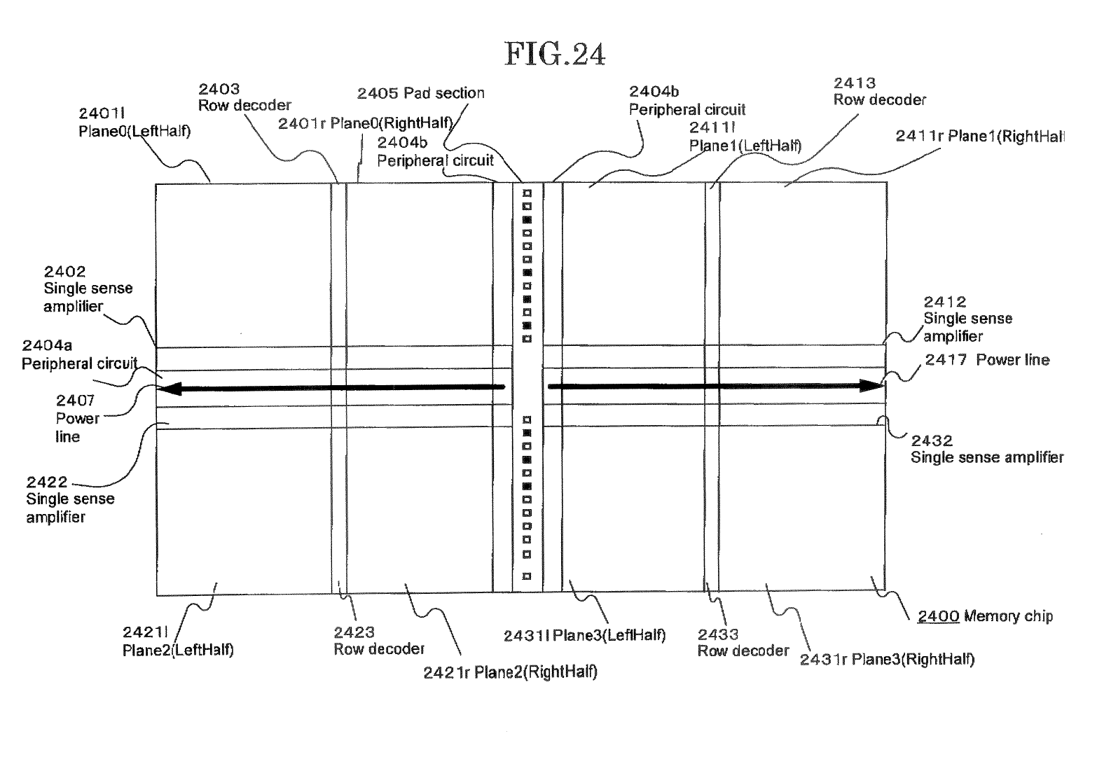

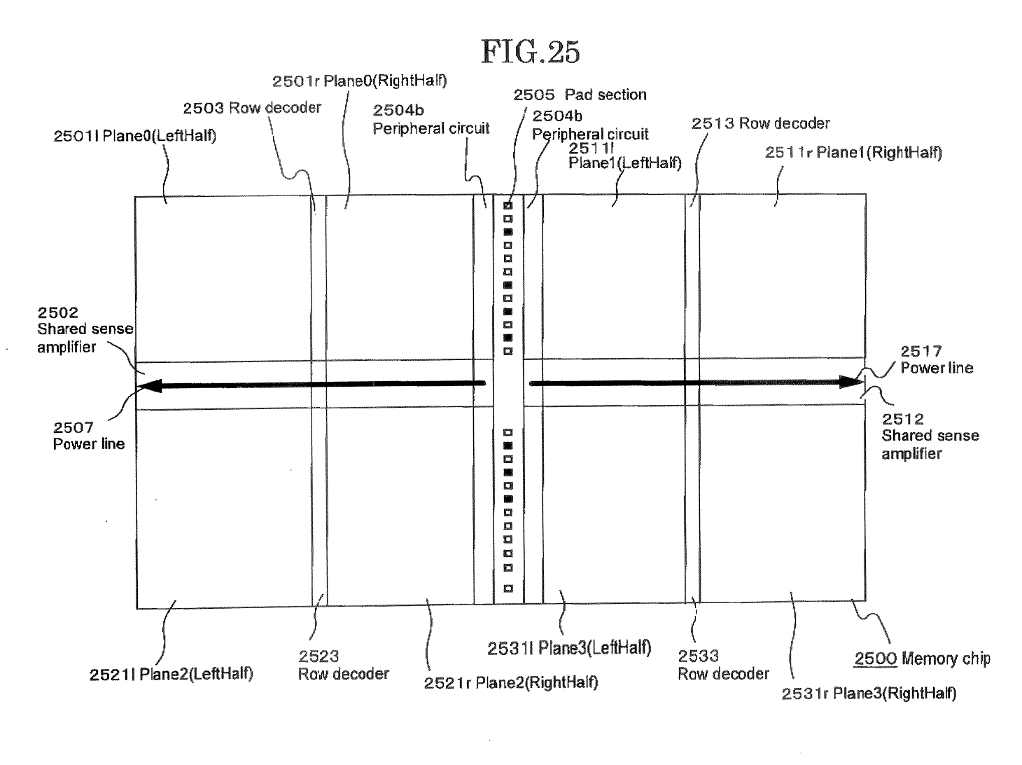

When there are four planes and the respective four planes are dual-partitioned to provide eight planes, in addition to the above layouts as shown in FIG. 18 to FIG. 21 in which each plane is divided on the short side center line of the each plane and a pad section is placed on the chip short side center line, another layout also may be considered where each plane is divided on the long side center line of the each plane to left and right parts and a pad section is placed on the chip long side center line. FIG. 22 to FIG. 25 are a data wiring diagram and a power wiring diagram of such a layout respectively. This layout also requires an additional use of a PB penetration wiring in order to minimize the respective data wiring lengths. The additional use of a PB penetration wiring can provide a wiring to a chip end with the minimum distance, can solve a problem of skew, and can minimize the wiring width. This layout is effective for a case where such a layout is cannot be avoided due to a limitation on a chip layout or the convenience of a layering.

### EMBODIMENT 5

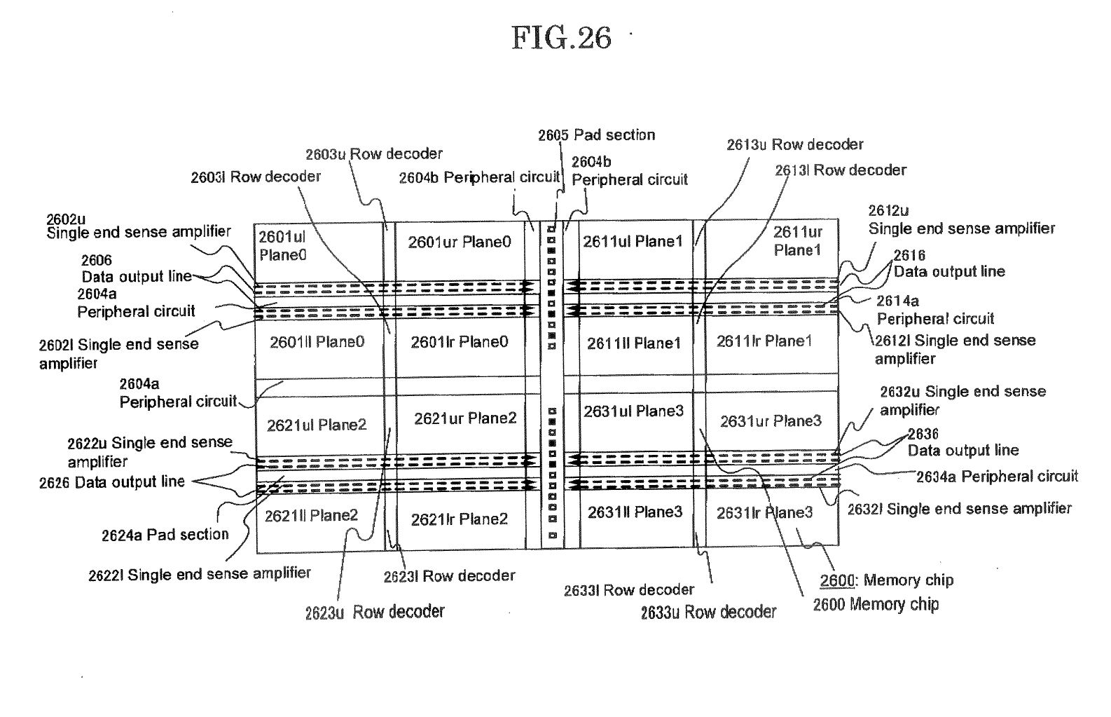

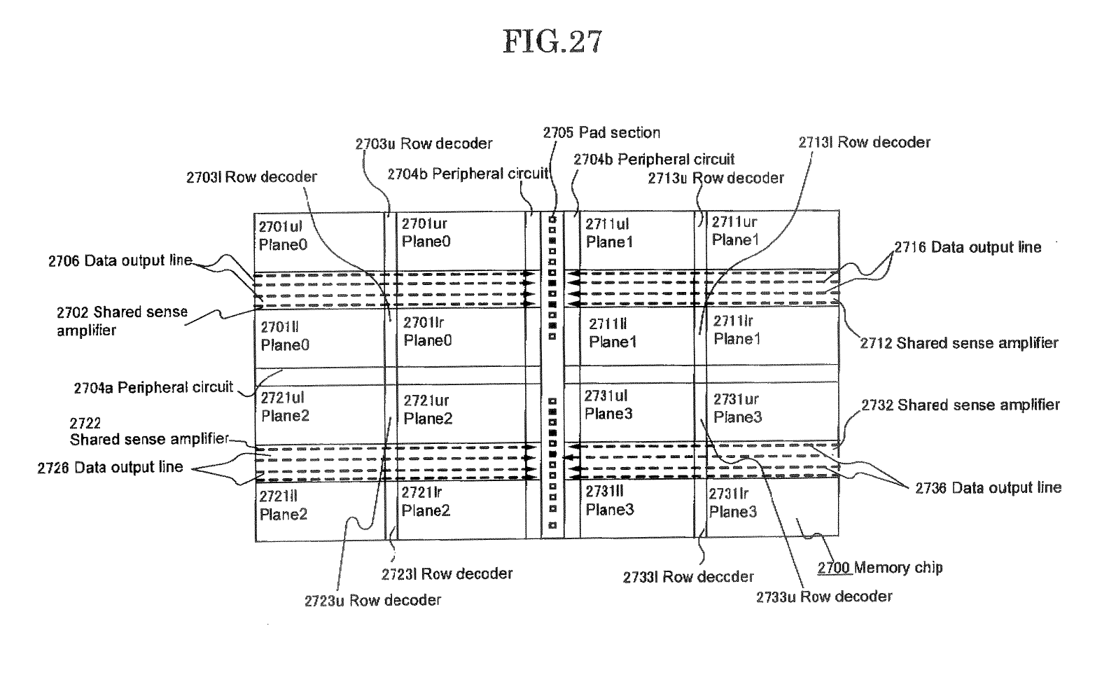

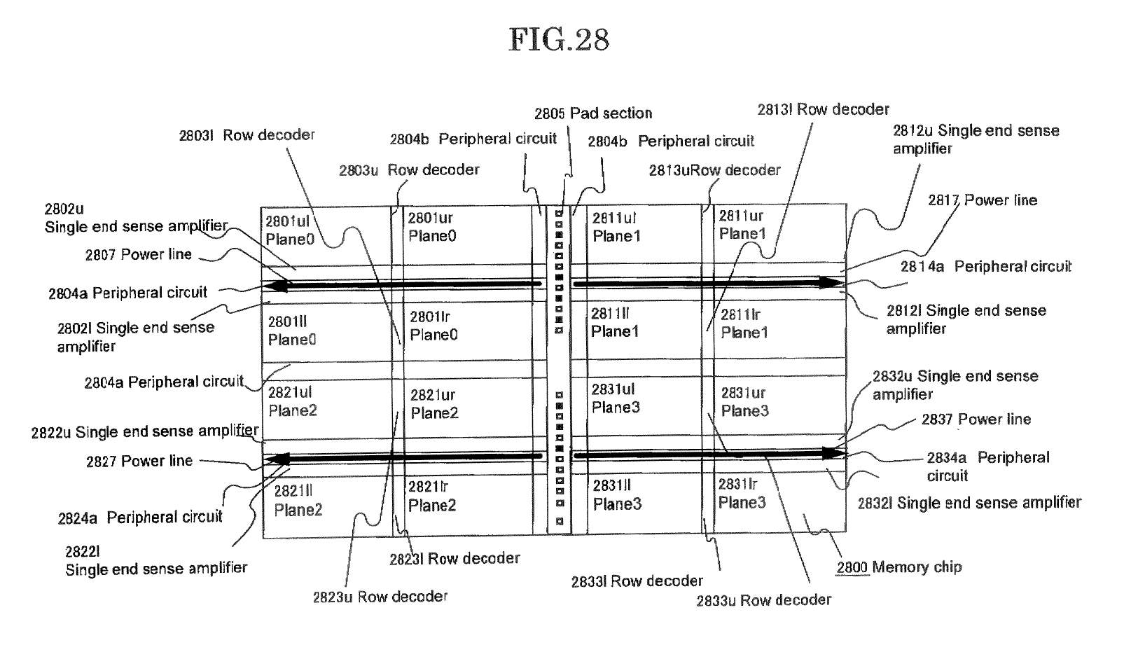

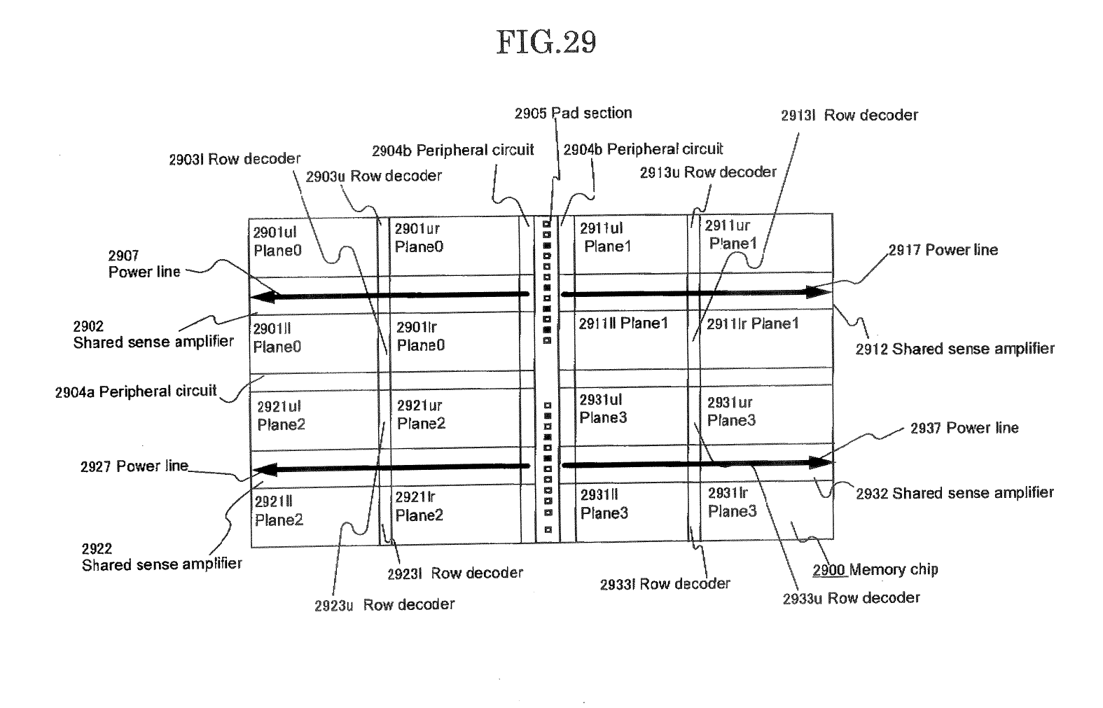

Furthermore, a higher capacity in the future can be flexibly coped with by providing a pad section on the chip long side center line or on the chip short side center line and by additionally using a PB penetration wiring. Embodiment 5 illustrates an example of a nonvolatile semiconductor memory device according to one embodiment of the present invention in which the respective four planes are divided to four upper and lower and left and right parts and a pad section is placed on the chip long side center line or on the chip short side center line. FIG. 26 is a schematic view of a chip layout of a NAND-type flash memory which has each of the four planes divided to four parts of UpperLeftHalf, UpperRightHalf, LowerLeftHalf, and LowerRightHalf, single end S/As, and a pad section placed on the chip long side center line according to one embodiment of the present invention. With regards to a pad section 2605 placed on the long side center line of a chip 2600, a data output line 2606 from a plane 0 is subjected to a PB penetration wiring and thus the minimum wiring from four divided planes 2601UL, 2601UR, 2601LL, and 2601LR to the pad section can be achieved. However, the planes 2601UL and the 2601LL have different wiring lengths from wiring length 2601UR and 2601LR and thus CR delay is caused. However, the CR delay can be minimized. This also applies to lines 2616, 2626, and 2636 from other planes. However, the respective data output wirings 2606, 2616, 2626, and 2636 have an equal wiring length. Thus, CR delay in the entire chip can be minimized and thus a problem of skew can be suppressed. When shared S/As are used as sense amplifiers in the same plane layout, a layout as shown in FIG. 27 is obtained. The layout as shown in FIG. 27 also requires an additional use of a PB penetration wiring but provides the same effect. In this case, the minimum power source wiring as shown in FIG. 28 and FIG. 29 from a pad section at the chip center to a chip end can be obtained. Thus, the power source line width can be minimized. Although not shown, when pad section is placed on the chip short side center line in the same plane layout above, the use of a PB penetration wiring can provide a data output wiring in which CR delay can be minimized and a power source wiring in which a power source line width can be minimized even when any of single end S/As or shared S/As are used as sense amplifiers.

### EMBODIMENT 6

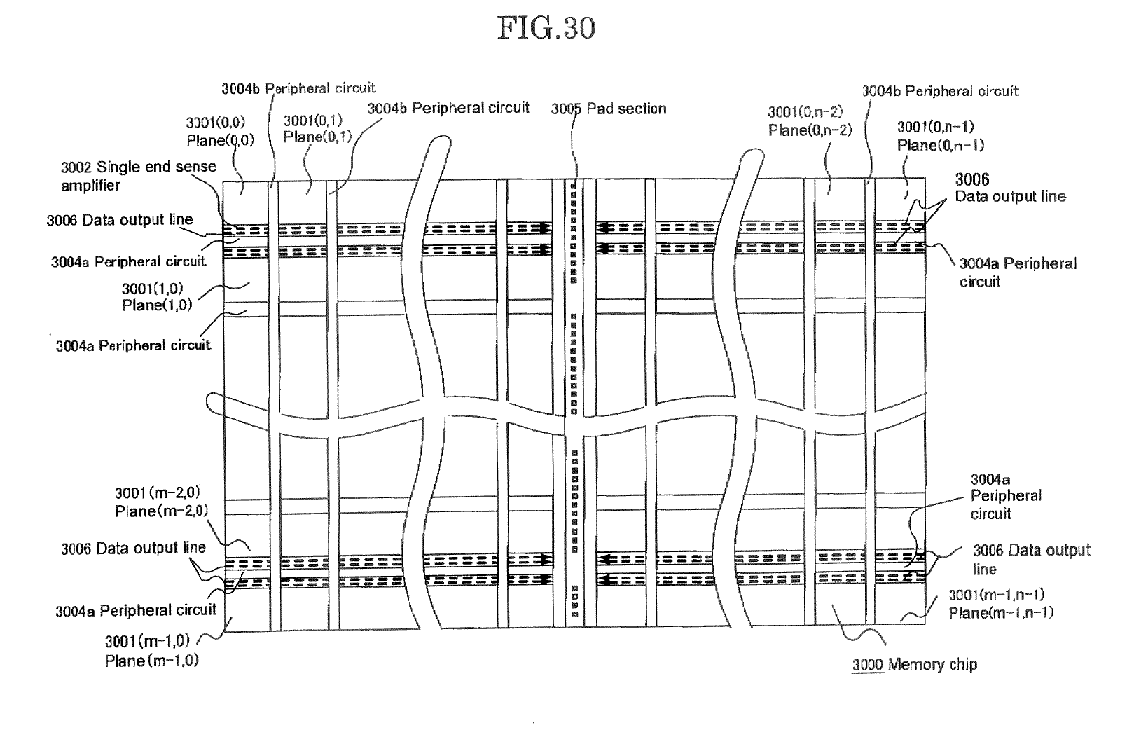

When a pad section is placed on the chip long side center line or on the chip short side center line and a PB penetration wiring is additionally used, such a nonvolatile semiconductor memory device can be provided that can cope with a demand for a further higher capacity. Embodiment 6 illustrates a nonvolatile semiconductor memory device according to one embodiment of the present invention when the number of planes is significantly increased. FIG. 30 is a schematic view of a chip layout of a NAND-type flash memory which has “M” planes arranged in a longitudinal direction and “N” planes arranged in a lateral direction, single end S/As are used as sense amplifiers, and a pad section placed on the chip long side center line according to one embodiment of the present invention. A pad section 3005 is placed on a position on the long side center line of a chip 3000 and data output lines 3006 of “M×2” PB penetration wirings are wired from left and right planes to the pad section to the pad section 3005. In this case, wirings from the respective planes are required and thus one large wiring 3006 includes therein “N/2” wirings having different line lengths. However, when considering the entire chip, “M×2” large wirings 3006 extending from the chip end to the pad section can be wired from the chip end with the minimum distance. Thus, skew due to CR delay can be minimized. The power line also can be extended from the pad section to the chip end with the minimum distance. Thus, the power wiring width can be minimized by placing the pad section on the chip long side center line in case of the same chip layout.

In Embodiment 6, “M” planes are arranged in a longitudinal direction and “N” planes are arranged in a lateral direction and a relation of M≦N is established. When a relation of M≧N is established, the same effect is obtained by placing a pad section on the chip short side center line. This shows the advantage by the pad section placed on the chip long side center line or on the chip short side center line over a conventional layout where a pad section is placed on a chip end. It is noted that any of the layouts requires “N” or “M” cells placed on the pad section at parallel positions in an amount of an even number but “N” or “M” cells placed in a direction orthogonal to the pad section may be in an amount of an odd number. When a relation of M=N is established, a pad section may be placed on the chip long side center line or on the chip short side center line can be positioned in accordance with a chip packaging space.

### EMBODIMENT 7

The number of layered chips can be increased in System in Package (SiP) in which circuits corresponding to various functions are formed by individual chips and the chips are combined and layered depending on an objective by the manner as described below. Specifically, in a bare chip in which a pad section according to the present invention is placed on the chip long side center line or on the chip short side center line, the pad section is penetrated to provide a through hole and the through hole is filled with conductive material (e.g., Cu). And bump-like conductive materials are formed on the surface simultaneously or after the formation of the through hole and filled with conductive materials interior thereof. Then, the chips are layered by bonding resin and soon, and electrodes protruding from the resin in a bump-like manner are electrically connected and thus the electrodes are formed to penetrate the plurality of chips (hereinafter referred to as a penetration electrode). Thus, an increased number of chips can be layered by using the penetration electrode. Also a higher capacity can be coped with and a packaging area and an attachment height can be suppressed. In Embodiment 7, the nonvolatile semiconductor memory device according to one embodiment of the present invention in which a pad section is placed on the chip long side center line or on the chip short side center line is layered by using the penetration electrode. It is noted that a penetration electrode is structured to have a penetration hole penetrating a semiconductor substrate corresponding to a lower part of connection regions of plural chips to the lower face and the interior thereof is filled with a conductive material. However, the penetration electrode also may be structured so that plural chips are layered to simultaneously form a through hole and the hole is filled with metal such as Cu or conductive semiconductor substance to penetrate the plurality of chips.

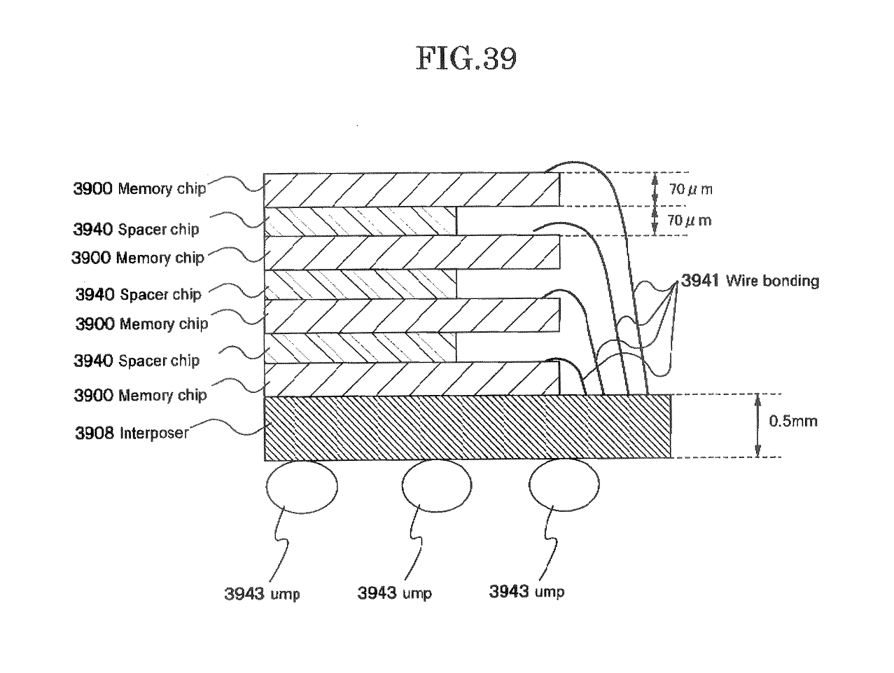

FIG. 39 illustrates an example where NADN-type flash memories including a pad section placed on a chip end respectively are layered by a wire bonding. A projection-like connection electrode bumps 3943 for directly connecting electrodes are provided on a substrate or a on a lead (not shown). The bumps 3943 have thereon an interposer 3908 and memory chips 3900 in a layered manner. In this case, the memory chips 3900 are connected with the interposer 3908 by wire bonding 3941. Thus, the wiring is curved to go over the upper face of the respective chips. Thus, spacer chips 3940 must be inserted between memory chips. This has been a cause of the limitation on the number of chips that can be layered.

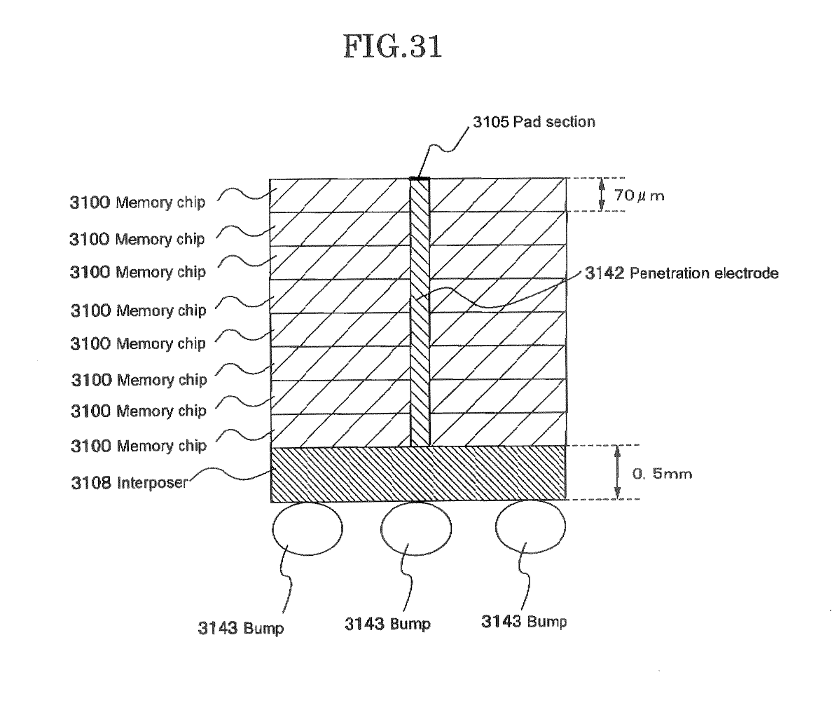

As shown in FIG. 31, by the nonvolatile semiconductor memory device according to one embodiment of the present invention in which a pad section is placed on the chip long side center line or on the chip short side center line, a combination of a layered package with a penetration electrode allows a penetration electrode 3142 to be placed at a pad section 3105 at the center part of a chip 3100. When these chips are layered to a package, a spacer chip is not required. Specifically, projection-like connection electrode bumps 3143 for directly connecting electrodes are provided on a substrate or on a lead (not shown) The bumps 3143 have thereon an interposer 3108 and memory chips 3100 in a layered manner. The use of the penetration electrode 3142 eliminates the need for a spacer chip. Then, a package is attached at a height of 1 mm is assumed. A height of a NAND-type flash memory is 70 μm and a height of a space chip is 70 μlm. In consideration of a height of an interposer of 0.5 mm, four flash memories can be layered when a conventional wire bonding is used (NAND-type flash memory 70 μm×4+space chip 70 μm×3=0.49 mm). When the combination of the pad section layout according to the present invention and a penetration electrode is used on the other hand, a memory having about two times higher capacity can be sealed for the same attachment height (NAND-type flash memory 70 μm×8=0.56 mm).

When a conventional wire bonding is used, wirings in packages from the respective layered NAND-type flash memories are drawn in a complicated manner and thus an interposer having a thickness smaller than 0.5 mm is required. When the combination of the nonvolatile semiconductor memory device according to the present invention and a penetration electrode is used on the other hand, chips can be directly connected and thus wirings in a package can be drawn in a simple manner. Thus, an interposer can have a reduced thickness of 0.15 mm to 0.2 mm. Thus, by the elimination of the need for the above space chip, a memory having a two times or higher capacity can be sealed when the same package attachment height is assumed. Furthermore, a wire bonding space of the interposer is not required and thus the interposer can have the same area as that of a layered NAND-type flash memory. Thus, a reduced packaging area also can be realized.

We claim:

1. A nonvolatile semiconductor memory device comprising:
a first memory cell array including a plurality of electrical reprogramming and erasable nonvolatile semiconductor memory cells formed in a first area of a semiconductor substrate;
a second memory cell array including a plurality of electrical reprogramming and erasable nonvolatile semiconductor memory cells formed in a second area different from said first area of said semiconductor substrate, said first and second memory cell arrays being arranged in a first direction; and
a first pad section for inputting data to and outputting data from said first memory cell array and said second memory cell array, said first pad section having a plurality of pads arranged between said first memory cell array and said second memory cell array along a second direction perpendicular to said first direction.

2. The nonvolatile semiconductor memory device according to claim 1, wherein;
said first memory cell array is divided into a first and second planes, said first and second planes being arranged in said second direction; and
said second memory cell array is divided into a third and fourth planes, said third and fourth planes being arranged in said second direction;
said nonvolatile semiconductor memory further comprising:
a first data line for supplying data from said first plane to said first pad section, said first data line being arranged between said first plane and said second plane along said first direction;
a second data line for supplying data from said second plane to said first pad section, said second data line being arranged between said first plane and said second plane along said first direction;
a third data line for supplying data from said third plane to said first pad section, said third data line being arranged between said third plane and said fourth plane along said first direction; and
a fourth data line for supplying data from said fourth plane to said first pad section, said fourth data line being arranged between said third plane and said fourth plane along said first direction.

3. The nonvolatile semiconductor memory device according to claim 2 further comprising:
a first sense amplifier connected to said first data line and being arranged between said first plane and said second plane along said first direction;
a second sense amplifier connected to said second data line and being arranged between said first plane and said second plane along said first direction;
a third sense amplifier connected to said third data line and being arranged between said third plane and said fourth plane along said first direction; and
a fourth sense amplifier connected to said fourth data line and being arranged between said third plane and said fourth plane along said first direction.

4. The nonvolatile semiconductor memory device according to claim 3 wherein:
each of said first sense amplifier, said second sense amplifier, said third sense amplifier and said fourth sense amplifier has plural single ended sense amplifiers;
said nonvolatile semiconductor memory device further comprising:
a first peripheral circuit including a circuit for driving said first sense amplifier and said second amplifier, said first peripheral circuit being arranged between said first sense amplifier and said second sense amplifier; and
a second peripheral circuit including a circuit for driving said third sense amplifier, said second sense amplifier being arranged between said third sense amplifier and said fourth sense amplifier.

5. The nonvolatile semiconductor memory device according to claim 1 further comprising:
a first row decoder for selecting word lines in said first memory cell array, said first row decoder being arranged between said first memory cell array and said first pad section; and
a second row decoder for selecting word lines in said second memory cell array, said second row decoder being arranged between said second memory cell array and said first pad section.

6. The nonvolatile semiconductor memory device according to claim 5 further comprising:
a third peripheral circuit including a circuit for driving said first row decoder, said third peripheral circuit being arranged between said first pad section and said first row decoder along said second direction; and
a fourth peripheral circuit including a circuit for driving said second row decoder, said fourth peripheral circuit being arranged between said first pad section and said second row decoder along said second direction.

7. The nonvolatile semiconductor memory device according to claim 3 wherein:
each of said first sense amplifier, said second sense amplifier, said third sense amplifier and said fourth sense amplifier has plural shared sense amplifiers.

8. The nonvolatile semiconductor memory device according to claim 7 further comprising:
a first row decoder for selecting word lines in said first memory cell array, said first row decoder being arranged between said first memory cell array and said first pad section; and
a second row decoder for selecting word lines in said second memory cell array, said second row decoder being arranged between said second memory cell array and said first pad section.

9. The nonvolatile semiconductor memory device according to claim 8 further comprising:
a fifth peripheral circuit including circuits for driving said first row decoder and said first and second sense amplifier, said fifth peripheral circuit being arranged between said first pad section and said first row decoder along said second direction; and
a sixth peripheral circuit including circuits for driving said second row decoder and said third and fourth sense amplifier, said sixth peripheral circuit being arranged between said first pad section and said second row decoder along said second direction.

10. The nonvolatile semiconductor memory device according to claim 1 further comprising:
a first power line for supplying power from said first pad section to said first memory cell array, said first power line being arranged in said first direction; and
a second power line for supplying power from said first pad section to said second memory cell array, said second power line being arranged in said first direction.

11. The nonvolatile semiconductor memory device according to claim 1 wherein:
said first memory cell array is divided into a first and second planes, said first and second planes being arranged in said first direction; and
said second memory cell array is divided into a third and fourth planes, said third and fourth planes being arranged in said first direction;
said nonvolatile semiconductor memory further comprising;
a first data line for supplying data from said first plane to said first pad section, said first data line being arranged in said first and second planes along said first direction;
a second data line for supplying data from said second plane to said first pad section, said second data line being arranged in said first and second planes along said first direction;
a third data line for supplying data from said third plane to said first pad section, said third data line being arranged in said third and fourth planes along said first direction; and
a fourth data line for supplying data from said fourth plane to said first pad section, said fourth data line being arranged in said third and fourth planes along said first direction.

12. The nonvolatile semiconductor memory device according to claim 11 further comprising:
a first sense amplifier connected to said first data line and being arranged in said first plane along said first direction;
a second sense amplifier connected to said second data line and being arranged in said second plane along said first direction;
a third sense amplifier connected to said third data line and being arranged in said third plane along said first direction; and
a fourth sense amplifier connected to said fourth data line and being arranged in said fourth plane along said first direction.

13. The nonvolatile semiconductor memory device according to claim 12 further comprising:
a first row decoder for selecting word lines in said first memory cell array, said first row decoder being arranged between said first plane and said second plane along said second direction; and
a second row decoder for selecting word lines in said second memory cell array, said second row decoder being arranged between said third plane and said fourth plane along said second direction.

14. The nonvolatile semiconductor memory device according to claim 13 further comprising:
a seventh peripheral circuit including circuits for driving said first and second sense amplifier and said first row decoder, said seventh peripheral circuit being arranged adjacent to said first and second sense amplifier along said first direction; and
a eighth peripheral circuit including circuits for driving said third and fourth sense amplifier and said second row decoder, said eighth peripheral circuit being arranged adjacent to said third and fourth sense amplifier along said first direction.

15. The nonvolatile semiconductor memory device according to claim 1 wherein:
said electrically reprogrammable and erasable nonvolatile memory cells are arranged to be NAND type.

16. The nonvolatile semiconductor memory device according to claim 1 further comprising:
a third memory cell array including a plurality of electrical reprogramming and erasable nonvolatile semiconductor memory cells formed in a third area different from said first and second area of a semiconductor substrate, said first and third memory cell arrays being arranged in said second direction;
a fourth memory cell array including a plurality of electrical reprogramming and erasable nonvolatile semiconductor memory cells formed in a fourth area different from said first, second and third area of said semiconductor substrate, said second and fourth memory cell arrays being arranged in said second direction, said third and fourth memory cell arrays being arranged in said first direction; and
a second pad section for inputting data to and outputting data from said third memory cell array and said fourth memory cell array, said second pad section having a plurality of pads arranged between said third memory cell array and said fourth memory cell array along said second direction, said first and second pad sections being arranged in said second direction.

17. A semiconductor device comprising:
a first nonvolatile semiconductor memory device comprising:
a first memory cell array including a plurality of electrical reprogramming and erasable nonvolatile semiconductor memory cells formed in a first area of a first semiconductor substrate;
a second memory cell array including a plurality of electrical reprogramming and erasable nonvolatile semiconductor memory cells formed in a second area different from said first area of said first semiconductor substrate, said first and second memory cell arrays being arranged in a first direction; and
a first pad section for inputting data to and outputting data from said first memory cell array and said second memory cell array, said first pad section having a plurality of pads arranged between said first memory cell array and said second memory cell array along a second direction perpendicular to said first direction; and
a second nonvolatile semiconductor memory device comprising:
a third memory cell array including a plurality of electrical reprogramming and erasable nonvolatile semiconductor memory cells formed in a third area of a second semiconductor substrate;
a fourth memory cell array including a plurality of electrical reprogramming and erasable nonvolatile semiconductor memory cells formed in a fourth area different from said third area of said second semiconductor substrate, said third and fourth memory cell arrays being arranged in a first direction; and
a second pad section for inputting data to and outputting data from said third memory cell array and said fourth memory cell array, said second pad section having a plurality of pads arranged between said third memory cell array and said fourth memory cell array along said second direction,
wherein said first substrate and second substrate are stacked, and said plurality of pads in said first pad section and said plurality of pads in said second pad section are connected via a through hole wiring formed in respective substrates of said first and second nonvolatile semiconductor memory devices.

18. The semiconductor device according to claim 17 further comprising:
an interposer attached and arranged below said first semiconductor substrate; and
a plurality of bumps formed on said interposer, each of said plurality of bumps being connected to respective one of said plurality of pads of said fast pad section or said second pad section.

19. The semiconductor device according to claim 17 wherein: said electrically reprogrammable and erasable nonvolatile memory cells are arranged to be NAND type.

20. The semiconductor device according to claim 17 wherein: said first semiconductor substrate and said second semiconductor substrate are stacked without inserting spacer chip.
